(19) United States
(12) Patent Application Publication
(10) Pub. No.: US 2023/0397445 A1
(43) Pub. Date: Dec. 7, 2023

(54) SEMICONDUCTOR MEMORY DEVICE

(71) Applicant: Kioxia Corporation, Tokyo (JP)

(72) Inventor: Hisashi KATO, Yokkaichi Mie (JP)

(73) Assignee: Kioxia Corporation, Tokyo (JP)

(21) Appl. No.: 18/175,873

(22) Filed: Feb. 28, 2023

(30) Foreign Application Priority Data
Jun. 3, 2022 (JP) 2022-090702

(51) Int. Cl. H10B 80/00

(52) U.S. Cl. CPC H10B 80/00

(57) ABSTRACT

A semiconductor memory device includes a first chip, a second chip, a third chip, and a fourth chip. The second chip is bonded to the first chip. The third chip is bonded to the second chip on a side opposite to the first chip. The fourth chip is bonded to the third chip on a side opposite to the second chip. The third chip includes a first stacked body in which a plurality of first conductive layers are stacked in a first direction. The second chip includes a second stacked body in which a plurality of second conductive layers are stacked in the first direction. The first and second conductive layers each longitudinally extend in a second direction perpendicular to the first direction. The fourth chip includes a plurality of line patterns each extending in the second direction and aligned with each other in a third direction.

### CROSS-REFERENCE TO RELATED APPLICATION

This application is based upon and claims the benefit of priority from Japanese Patent Application No. 2022-090702, filed Jun. 3, 2022, the entire contents of which are incorporated herein by reference.

### FIELD

Embodiments described herein relate generally to a semiconductor memory device.

### BACKGROUND

A semiconductor memory device may be configured by bonding a plurality of chips. It is generally desirable to bond the plurality of chips appropriately to each other in a semiconductor memory device.

### DESCRIPTION OF THE DRAWINGS

FIG. 1 is a block diagram illustrating a configuration of a semiconductor memory device according to an embodiment.

FIG. 2 is a circuit diagram illustrating a configuration of a block according to an embodiment.

FIG. 3 is a cross-sectional view in a stacking direction illustrating a configuration of the semiconductor memory device according to the embodiment.

FIG. 4 is a cross-sectional view in the stacking direction illustrating the configuration of the semiconductor memory device according to the embodiment.

FIG. 5 is a cross-sectional view in the stacking direction illustrating the configuration of the semiconductor memory device according to the embodiment.

FIGS. 6A and 6B are cross-sectional views in a planar direction and a stacking direction illustrating a configuration of a memory cell according to an embodiment.

FIG. 7 is an exploded perspective view illustrating the configuration of the semiconductor memory device according to the embodiment.

FIGS. 8A and 8B are views illustrating functions of a support chip according to an embodiment.

FIGS. 9A and 9B are views illustrating functions of the support chip according to the embodiment.

FIG. 10 is a cross-sectional view illustrating a configuration of a semiconductor memory device according to a first modification example of an embodiment.

FIG. 11 is a cross-sectional view illustrating the configuration of the semiconductor memory device according to the first modification example of the embodiment.

FIG. 12 is a cross-sectional view illustrating the configuration of the semiconductor memory device according to the first modification example of the embodiment.

FIG. 13 is an exploded perspective view illustrating the configuration of the semiconductor memory device according to the first modification example of the embodiment.

FIGS. 14A to 14E are cross-sectional views illustrating a method of manufacturing a semiconductor memory device, according to a second modification example of the embodiment.

FIGS. 15A and 15B are plan views illustrating a method of manufacturing a semiconductor memory device according to the second modification example of the embodiment.

FIGS. 16A to 16C are cross-sectional views illustrating patterns in each chip region of a supporting substrate according to the second modification example of the embodiment.

FIGS. 17A to 17C are cross-sectional views illustrating the method of manufacturing the semiconductor memory device, according to the second modification example of the embodiment.

FIGS. 18A and 18B are cross-sectional views illustrating the method of manufacturing the semiconductor memory device according to the second modification example of the embodiment.

FIGS. 19A to 19C are cross-sectional views illustrating a method of manufacturing a semiconductor memory device, according to a third modification example of the embodiment.

FIGS. 20A to 20C are cross-sectional views illustrating the method of manufacturing the semiconductor memory device according to the third modification example of the embodiment.

FIGS. 21A and 21B are cross-sectional views illustrating the method of manufacturing the semiconductor memory device according to the third modification example of the embodiment.

### DETAILED DESCRIPTION

Embodiments provide a semiconductor memory device suitable for appropriately bonding a plurality of chips.

In general, according to one embodiment, a semiconductor memory device includes a first chip, a second chip, a third chip, and a fourth chip. The second chip is bonded to the first chip. The third chip is bonded to the second chip on a side opposite to the first chip. The fourth chip is bonded to the third chip on a side opposite to the second chip. The third chip includes a first stacked body in which a plurality of first conductive layers are stacked in a first direction through a first insulating layer, a plurality of first semiconductor films each extending in the first direction through the first stacked body, and a plurality of first insulating films each extending in the first direction outside the first semiconductor film through the first stacked body. The second chip includes a second stacked body in which a plurality of second conductive layers are stacked in the first direction through a second insulating layer, a plurality of second semiconductor films each extending in the first direction through the second stacked body, and a plurality of second insulating films each extending in the first direction outside the second semiconductor film through the second stacked body. The first conductive layer longitudinally extends in a second direction perpendicular to the first direction. The second conductive layer longitudinally extends in the second direction. The fourth chip includes a plurality of line patterns each extending in the second direction and aligned with each other in a third direction perpendicular to the first direction and the second direction.

A semiconductor memory device according to an embodiment will be described in detail below with reference to the accompanying drawings. The present disclosure is not limited to the following embodiments.

### Embodiment

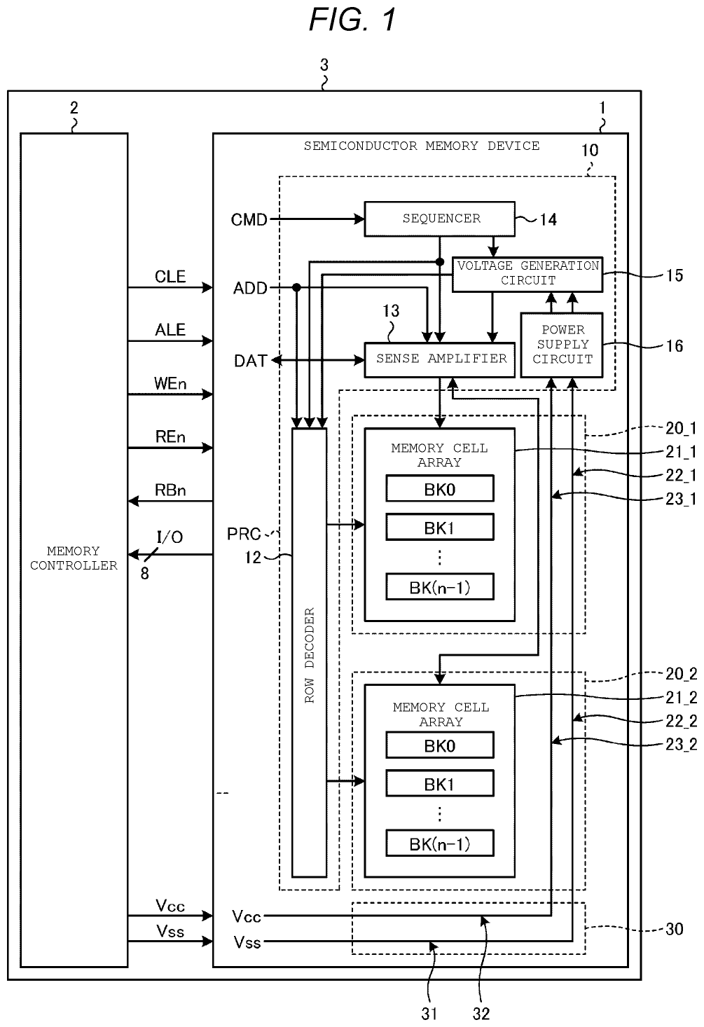

A semiconductor memory device according to an embodiment is configured by bonding a plurality of chips to each other and is devised to appropriately bond the plurality of chips. For example, a semiconductor memory device 1 may be configured as illustrated in FIG. 1. FIG. 1 is a block diagram illustrating a configuration of the semiconductor memory device 1.

The semiconductor memory device 1 includes a plurality of chips 10, 20_1, 20_2, and 30. The chips 20_1 and 20_2 respectively include memory cell arrays 21_1 and 21_2 and are also called array chips. The chip 10 includes a circuit for controlling the memory cell arrays 21_1 and 21_2 and is also called a circuit chip. The chip 30 includes a pattern for flatly supporting the other chips 10, 20_1, and 20_2 and is also called a support chip.

The chips 20_1 and 20_2 are referred to as chips 20 when not distinguished from each other. The memory cell arrays 21_1 and 21_2 are referred to as memory cell arrays 21 when not distinguished from each other. Further, FIG. 1 illustrates a configuration in which the semiconductor memory device 1 includes two chips (array chips) 20_1 and 20_2, the semiconductor memory device 1 may include three or more array chips.

The semiconductor memory device 1 may be a nonvolatile memory (for example, a NAND flash memory) that stores data in a nonvolatile manner and may be applied to a memory system 3, such as a memory card or a solid state drive (SSD). The memory system 3 includes the semiconductor memory device 1 and a memory controller 2.

The semiconductor memory device 1 receives, from the memory controller 2, a power supply voltage Vss, a power supply voltage Vcc, a command latch enable signal CLE, an address latch enable signal ALE, a write enable signal WEn, a read enable signal REn, a ready-busy signal RBn, input/output signals I/O, and the like. The semiconductor memory device 1 is controlled by the memory controller 2 through the signals.

The input/output signals I/O may include a command CMD, address information ADD, and a data signal DAT. The power supply voltage Vss has a reference voltage (for example, a ground voltage). The power supply voltage Vcc has a predetermined voltage (for example, a power supply potential). The command latch enable signal CLE indicates that the input/output signal I/O is a command CMD. The address latch enable signal ALE indicates that the output signal I/O is address information ADD. The write enable signal WEn may be used when a write operation is enabled. The read enable signal REn may be used when a read operation is enabled. The ready-busy signal RBn indicates that the semiconductor memory device 1 is in a ready/busy state.

The chip 20_1 includes the memory cell array 21_1 and power supply lines 22_1 and 23_1. In the memory cell array 21_1, a plurality of memory cell transistors (hereinafter, simply referred to as memory cells) are arranged three-dimensionally. The chip 20_2 includes the memory cell array 21_2 and power supply lines 22_2 and 23_2. In the memory cell array 21_2, a plurality of memory cells are arranged three-dimensionally. Each memory cell array 21 includes a plurality of blocks BK.

The chip 30 includes power supply lines 31 and 32. The power supply voltage Vss is transmitted to the chip 10 via the power supply lines 31, 22_2, and 22_1. The power supply voltage Vcc is transmitted to the chip 10 via power supply lines 32, 23_2, and 23_1.

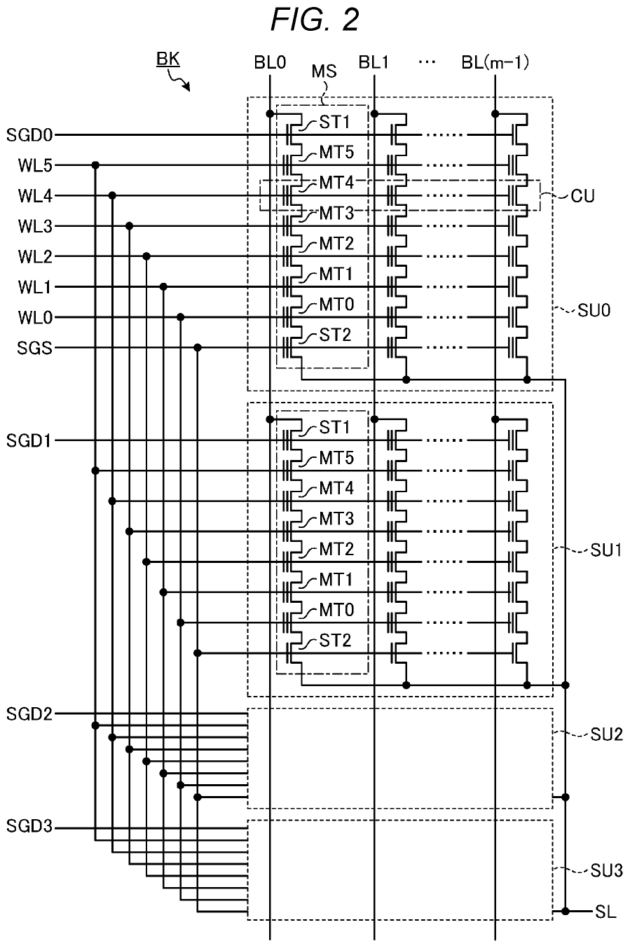

Each block BK corresponds to a set of a plurality of memory cells commonly connected to word lines WL and may be configured as illustrated in FIG. 2. FIG. 2 is a circuit diagram illustrating a configuration of the block BK.

The block BK includes, for example, four string units SU0-SU3. Each string unit SU includes a plurality of memory strings MS. A plurality of memory strings MS correspond to a plurality of bit lines BL0 to BL(m−1) (m is any integer of 2 or more). Each memory string MS is connected to a corresponding bit line BL. Each memory string MS includes memory cells MT0 to MT7 and select transistors ST1 and ST2.

In each memory string MS, a drain of the select transistor ST1 is connected to the bit line BL. The memory cells MT0 to MT7 are connected in series between a source of the select transistor ST1 and a drain of the select transistor ST2. A source of the select transistor ST2 is connected to a source line SL.

Gates of the select transistors ST1 of the memory strings MS included in the string unit SU are commonly connected to a select gate line SGD. Gates of the select transistors ST2 of the memory strings MS included in the block BK are commonly connected to a select gate line SGS. Gates of the memory cells MT of the memory string MS included in the block BK are commonly connected to the word line WL.

A set of memory cells MT, which are connected to one word line WL, in one string unit SU is referred to as a cell unit CU. For example, when the memory cell MT stores p-bit data (p is an integer of 1 or more), a storage capacity of the cell unit CU is defined as p page data.

Each bit line BL is connected to the drain of the select transistor ST1 of the corresponding memory string MS of each string unit SU of the block BK. The source line SL is commonly connected to sources of the select transistors ST2 of the memory strings MS included in the block BK, and is shared among the string units SU of the block BK. The source line SL may be shared between the blocks BK.

The chip 10 (circuit chip) illustrated in FIG. 1 includes a row decoder 12, a sense amplifier 13, a sequencer 14, a voltage generation circuit 15, and a power supply circuit 16.

The power supply circuit 16 supplies the power supply voltages Vss and Vcc received from the chip 30 to each unit. For example, the power supply circuit 16 supplies the power supply voltage Vss and Vcc to the voltage generation circuit 15.

The sequencer 14 collectively controls each unit according to the command CMD. For example, the sequencer 14 controls a write operation according to the write command CMD. In controlling the write operation, the sequencer 14 writes data DAT to the addressed memory cell MT in the memory cell array 21 and returns a write completion notification to the memory controller 2. The sequencer 14 controls a read operation according to the read command CMD. In controlling the read operation, the sequencer 14 reads the data DAT from the addressed memory cell MT in the memory cell array 21 and returns the read data DAT to the memory controller 2.

The voltage generation circuit 15 generates a voltage according to a control of the sequencer 14 by using the power supply voltages Vss and Vcc and supplies the voltage to the row decoder 12 and the sense amplifier 13.

The row decoder 12 decodes the address information ADD, selects the word line WL corresponding to a memory cell to be written to or read from the memory cell array 21 according to the decoding result, and supplies a voltage to the selected word line WL.

The sense amplifier 13 decodes the address information ADD and selects the bit line BL corresponding to a memory cell to be written to or read from the memory cell array 21 according to the decoding result. The sense amplifier 13 supplies a voltage to the selected bit line BL during a write operation. The sense amplifier 13 supplies a voltage to the selected bit line BL and senses a voltage of the selected bit line BL during a read operation.

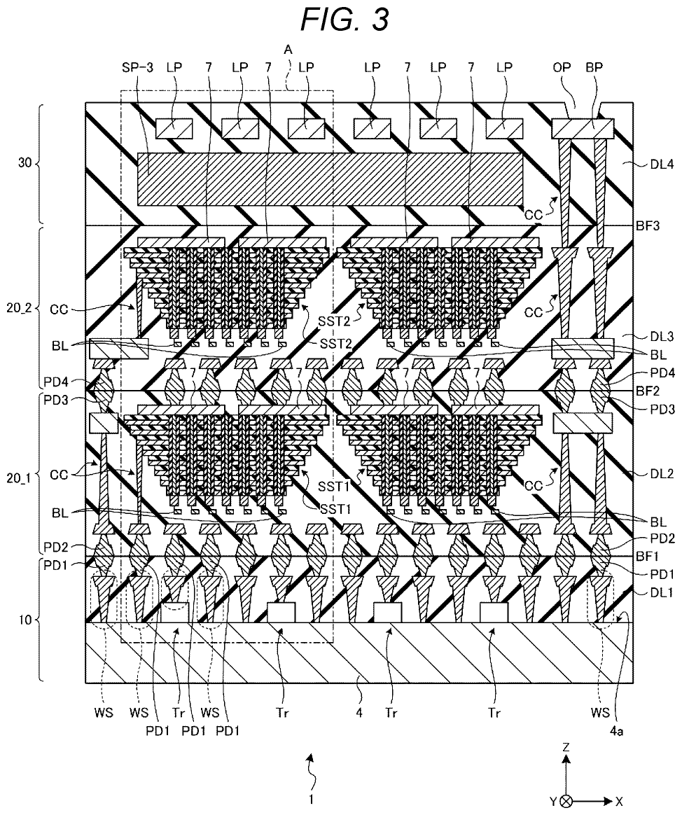

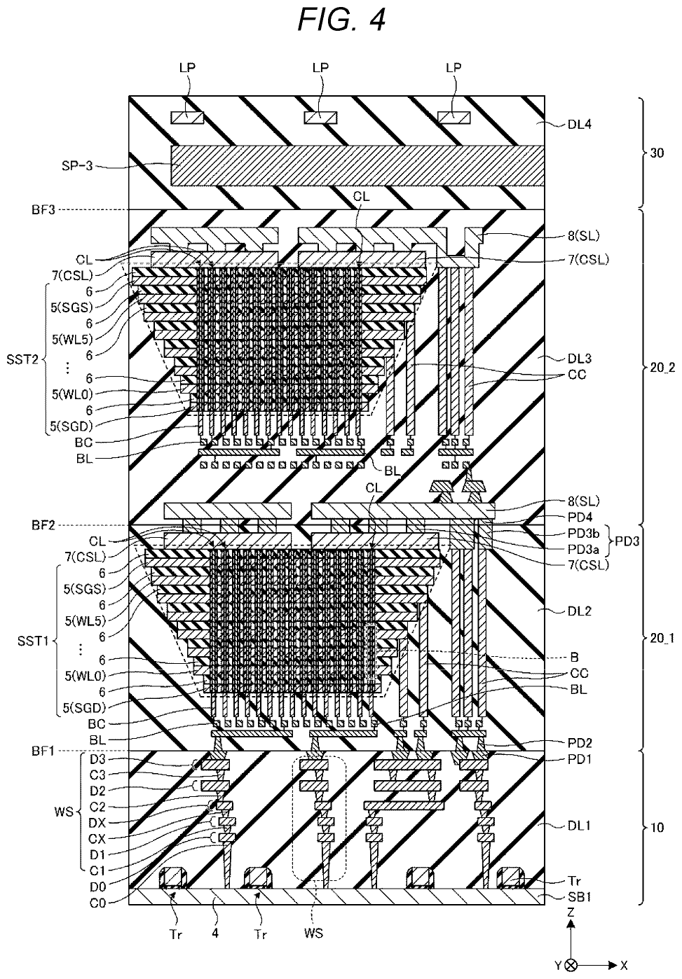

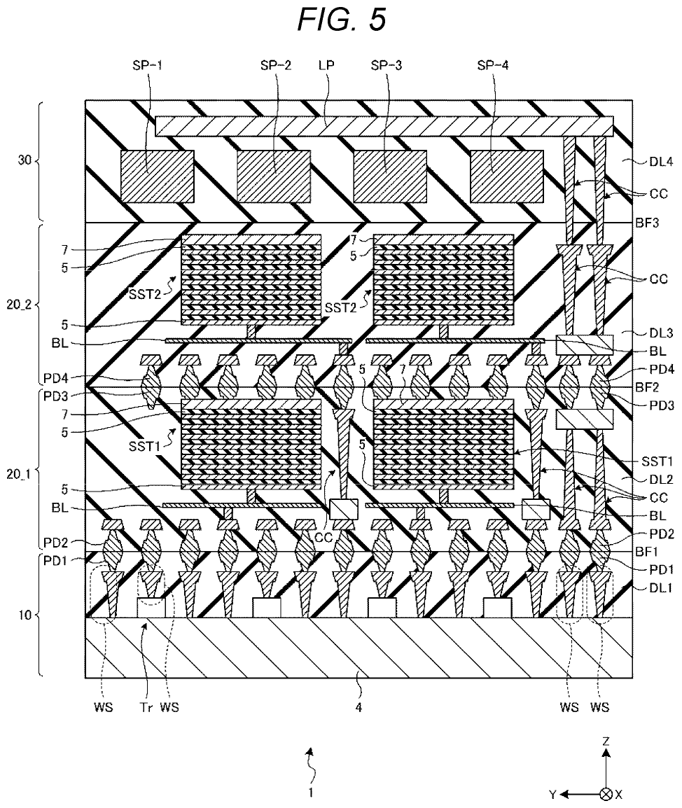

The semiconductor memory device 1 is configured by stacking the plurality of chips 10, 20_1, 20_2, and 30, as illustrated in FIGS. 3 to 5. Hereinafter, a stacking direction of the chips is defined as a Z direction, and two directions that are orthogonal to each other on a plane perpendicular to the Z direction are defined as an X direction and a Y direction. FIG. 3 is an XZ cross-sectional view schematically illustrating the configuration of the semiconductor memory device 1. FIG. 4 is an XZ cross-sectional view illustrating the configuration of the semiconductor memory device 1, and is a cross-sectional view illustrating an A portion of FIG. 3 in detail. FIG. 5 is a YZ cross-sectional view schematically illustrating the configuration of the semiconductor memory device 1.

In the semiconductor memory device 1, the plurality of chips 10, 20_1, and 20_2 are stacked. The chip 20_1 is disposed on a +Z side of the chip 10. The chip 20_2 is disposed on a +Z side of the chip 20_1. The chip 30 is disposed on a +Z side of the chip 20_2. That is, the chips 20_1, 20_2, and 30 are sequentially stacked on the +Z side of the chip 10. A structure in which the chips 20_1 and 20_2 are sequentially bonded to each other on the +Z side of the chip 10 is also called a multi-stack array, in which the memory cell arrays 21_1 and 21_2 are sequentially stacked. The structure illustrated in FIGS. 3 to 5 is a structure in which the chip (support chip) 30 is stacked in a multi-stack array.

The number of chips (array chips) 20 stacked in the multi-stack array is not limited to two and may be three or more.

The chip 20_1 is bonded to a surface on the +Z side of the chip 10. The chip 20_1 may be bonded by direct bonding. The chip 10 includes an insulating film (for example, an oxide film) DL1 and an electrode PD1 on the +Z side. The chip 20_1 includes an insulating film (for example, an oxide film) DL2 and an electrode PD2 on the −Z side. At a bonding surface BF1 between the chip 10 and the chip 20_1, the insulating film DL1 of the chip 10 and the insulating film DL2 of the chip 20_1 are bonded together, and the electrode PD1 of the chip 10 and the electrode PD2 of the chip 20_1 are bonded to each other.

The chip 20_2 is bonded to a surface on the +Z side of the chip 20_1. The chip 20_2 is bonded to the chip 20_1 on an opposite side of the chip 10. The chip 20_2 may be bonded by direct bonding. The chip 20_1 includes the insulating film (for example, an oxide film) DL2 and an electrode PD3 on the +Z side. The chip 20_2 includes an insulating film (for example, an oxide film) DL3 and an electrode PD4 on the −Z side. At a bonding surface BF2 of the chips 20_1 and 20_2, the insulating film DL2 of the chip 20_1 is bonded to the insulating film DL3 of the chip 20_2, and the electrode PD3 of the chip 20_1 is bonded to the electrode PD4 of the chip 20_2.

The chip 30 is bonded to a surface on the +Z side of the chip 20_2. The chip 30 is bonded to the chip 20_2 on an opposite side of the chip 20_1. The chip 30 may be bonded by direct bonding. The chip 20_2 includes an insulating film (for example, oxide film) DL3 on the +Z side. The chip 30 includes an insulating film (for example, oxide film) DL4 on the −Z side. At a bonding surface BF3 of the chips 20_2 and 30, the insulating film DL3 of the chip 20_2 is bonded to the insulating film DL4 of the chip 30.

The chip 10 includes a substrate 4, a transistor Tr, an electrode PD1, a wiring structure WS, and an insulating film DL1. The substrate 4 is disposed on the −Z side of the chip 10 and extends in a plate shape in XY directions. The substrate 4 may be a semiconductor substrate and may be formed of a material with a semiconductor (for example, silicon) as a main component. The substrate 4 has a surface 4a on the +Z side. The transistor Tr functions as a circuit element of a circuit (the row decoder 12, the sense amplifier 13, the sequencer 14, the voltage generation circuit 15, the power supply circuit 16, and the like) for controlling the memory cell array 21. The transistor Tr includes a gate electrode disposed as a conductive film on the surface 4a of the substrate 4, source electrode/drain electrode disposed as semiconductor regions near the surface 4a of the substrate 4, and the like. The electrode PD1 exposes a surface thereof to bonding surfaces BF1 of the chips 10 and 20_1, as described above. The wiring structure WS extends mainly in the Z direction and connects a gate electrode, source electrode/drain electrode, and the like of the transistor Tr to the electrode PD1. For example, the wiring structure WS may sequentially include a plug C0, a conductive film DO, a plug C1, a conductive film D1, a plug C2, a conductive film D2, a plug C3, and a conductive film D3 from the −Z side to the +Z side.

The chip 20_1 includes a stacked body SST1, conductive layers 7, a plurality of columnar bodies CL, a plurality of plugs CC, a plurality of conductive films BL, electrodes PD2, electrodes PD3, and an insulating film DL2.

The stacked body SST1 has a substantially isosceles trapezoidal shape in an XZ cross-sectional view and has a substantially rectangular shape in a YZ cross-sectional view. A substantially isosceles trapezoidal shape has an upper base that is longer than a lower base.

In the stacked body SST1, a plurality of conductive layers 5 are stacked in the Z direction through an insulating layer 6. The conductive layers 5 extend in a plate shape in the XY directions. The conductive layers 5 may each be formed of a material including a metal, such as tungsten, as a main component. The insulating layer 6 may each be formed of an insulating material, such as silicon oxide. The conductive layer 7 is disposed on the +Z side of the stacked body SST1. The conductive layers 7 extend in a plate shape in the XY directions.

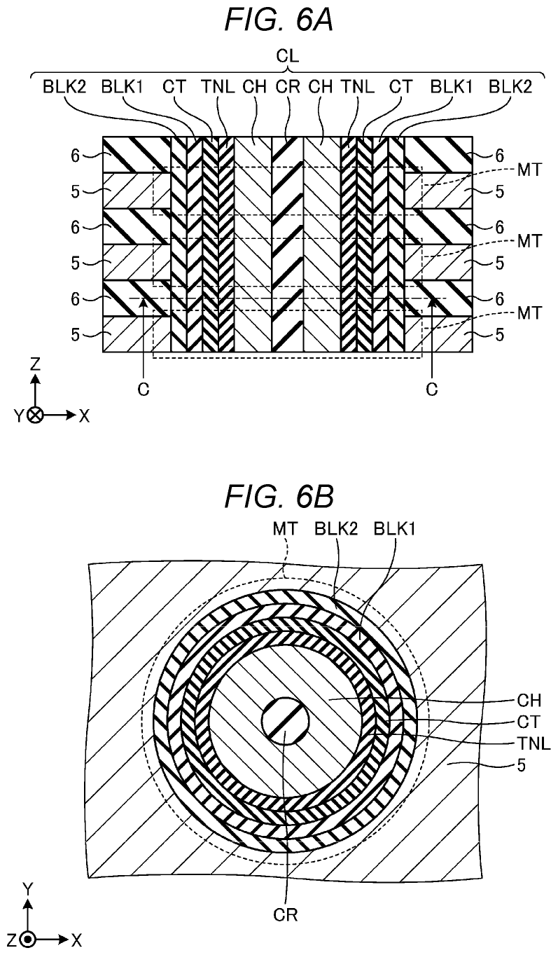

The respective columnar bodies CL extend in the Z direction through the plurality of conductive layers 5. The respective columnar bodies CL may penetrate the stacked body SST1 in the Z direction. The respective columnar bodies CL extend in a columnar shape in the Z direction. Each columnar body CL includes a semiconductor film CH (see FIG. 6) that functions as a channel region. The semiconductor film CH extends in a columnar shape (for example, a columnar shape or a cylindrical shape) having an axis along the Z direction. A plurality of memory cells MT are formed at a plurality of intersection positions where a plurality of conductive layers 5 intersect a plurality of columnar bodies CL, that is, a plurality of intersection positions where the plurality of conductive layers 5 intersect a plurality of semiconductor films CH.

Each columnar body CL includes an insulating film CR, a semiconductor film CH, an insulating film TNL, a charge storage film CT, an insulating film BLK1, and an insulating film BLK2 as illustrated in FIGS. 6A and 6B. FIG. 6A is an XZ cross-sectional view illustrating a configuration of the memory cell MT and is an enlarged cross-sectional view of a B portion of FIG. 4. FIG. 6B is an XY cross-sectional view illustrating the configuration of the memory cell MT and illustrates a cross section taken along line C-C in FIG. 6A. The insulating film CR extends in the Z direction and has a columnar shape having an axis along the Z direction. The insulating film CR may be formed of an insulating material, such as silicon oxide. The semiconductor film CH extends in the Z direction so as to cover the insulating film CR from the outside in the XY directions and has a cylindrical shape having an axis along the Z direction. The semiconductor film CH may be formed of a semiconductor, such as polysilicon. The insulating film TNL extends in the Z direction so as to cover the semiconductor film CH from the outside in the XY directions and has a cylindrical shape having an axis along the Z direction. The insulating film TNL may be formed of an insulating material, such as silicon oxide. The charge storage film CT extends in the Z direction so as to cover the insulating film TNL from the outside in the XY directions and has a cylindrical shape having an axis along the Z direction. The charge storage film CT may be formed of an insulating material, such as silicon nitride. The insulating film BLK1 extends in the Z direction so as to cover the charge storage film CT from the outside in the XY directions and has a cylindrical shape having an axis along the Z direction. The insulating film BLK1 may be formed of an insulating material, such as silicon oxide. The insulating film BLK2 extends in the Z direction so as to cover the insulating film BLK1 from the outside in the XY directions and has a cylindrical shape having an axis along the Z direction. The insulating film BLK2 may be formed of an insulating material, such as aluminum oxide. Portions surrounded by dotted lines in FIGS. 6A and 6B function as the memory cells MT.

As illustrated in FIG. 4, the semiconductor film CH in the columnar body CL has an end on the +Z side connected to the conductive layer 7 and has another end on the −Z side connected to the conductive film BL through a plug. The conductive film BL functions as the bit line BL (see FIG. 2). The conductive layer 7 may be formed of a semiconductor (for example, polysilicon) imparted with conductivity. A conductor 8 is disposed on the +Z side of the conductive layer 7. The conductor 8 has a projection portion extending in the −Z direction, and the end on the −Z side of the projection portion is in contact with the conductive layer 7. The conductor 8 extends in the XY directions from a region overlapping the conductive layer 52 to the outside thereof when viewed in the Z direction. The conductor 8 is connected to the plug CC on the −Z side outside the region overlapping the conductive layer 52. The conductive layer 7 functions as a cell source portion CSL in the source line SL (see FIG. 2). The conductor 8 functions as another portion of the source line SL. The semiconductor film CH functions as a channel region in the memory string MS (see FIG. 2).

Further, the respective conductive layers 5 may have the same width in the Y direction. The plurality of conductive layers 5 each have a width in the X direction increasing stepwise from the −Z side to the +Z side. The plurality of conductive layers 5 locate ends in the X direction gradually outward from the −Z side to the +Z side. Thereby, a stepwise structure is formed in which the select gate line SGD, the plurality of word lines WL0 to WL5, and the select gate line SGS are pulled out stepwise and sequentially from the −Z side to the +Z side at a plug connection portion in the memory cell array 11_1.

The plurality of plugs CC extend in the Z direction. The plug CC may have an end on the −Z side electrically connected to the electrodes PD2, extend in the Z direction, and have another end on the +Z side connected to the conductive layer 5. Thereby, the conductive layer 5 may be connected to the transistor Tr of the chip 10 via the plug CC, the electrode PD2, the electrode PD1, and the wiring structure WS. Alternatively, the plug CC may have the end on the −Z side electrically connected to the electrode PD2, extend in the Z direction, and have another end on the +Z side electrically connected to the electrode PD3. Thereby, the plugs CC may transmit power supply voltages, signals, and the like between the chip 10 and the chip 20_2.

A plurality of conductive films BL are disposed on the −Z side of the stacked body SST1. The plurality of conductive films BL are arranged in the X direction with each other. Each conductive film BL extends in the Y direction. The plurality of conductive films BL correspond to the plurality of columnar bodies CL. Each conductive film BL is electrically connected to the end on the −Z side of the corresponding columnar body CL and functions as the bit line BL. The conductive film BL is electrically connected to the electrode PD2. Thereby, the bit line BL may be connected to the transistor Tr of the chip 10 via the electrode PD2, the electrode PD1, and the wiring structure WS.

The electrode PD2 exposes a surface thereof to the bonding surface BF1 between the chip 10 and the chip 20_1, as described above. The electrode PD3 exposes a surface thereof to the bonding surface BF2 between the chip 20_1 and the chip 20_2, as described above.

The chip 20_2 includes a stacked body SST2, a conductive layer 7, a plurality of columnar bodies CL, a plurality of plugs CC, a plurality of conductive films BL, electrodes PD4, and an insulating film DL3.

The stacked body SST2 has a substantially isosceles trapezoidal shape in an XZ cross-sectional view and has a substantially rectangular shape in a YZ cross-sectional view. A substantially isosceles trapezoidal shape has an upper base that is longer than a lower base.

In the stacked body SST2, the plurality of conductive layers 5 are stacked in the Z direction through the insulating layer 6. The conductive layers 5 extend in a plate shape in the XY directions. The conductive layers 5 may each be formed of a material including a metal, such as tungsten, as a main component. The insulating layer 6 may each be formed of an insulating material, such as silicon oxide. The conductive layer 7 is disposed on the +Z side of the stacked body SST2. The conductive layers 7 extend in a plate shape in the XY directions.

Each columnar body CL may penetrate the stacked body SST2 in the Z direction. The respective columnar bodies CL extend in a columnar shape in the Z direction. Each columnar body CL includes a semiconductor film CH (see FIG. 6) that functions as a channel region. The semiconductor film CH extends in a columnar shape (for example, a columnar shape or a cylindrical shape) having an axis along the Z direction. A plurality of memory cells MT are formed at a plurality of intersection positions where a plurality of conductive layers 5 intersect a plurality of columnar bodies CL, that is, a plurality of intersection positions where the plurality of conductive layers 5 intersect a plurality of semiconductor films CH.

Each columnar body CL includes an insulating film CR, a semiconductor film CH, an insulating film TNL, a charge storage film CT, an insulating film BLK1, and an insulating film BLK2 as illustrated in FIGS. 6A and 6B. The insulating film CR extends in the Z direction and has a columnar shape having an axis along the Z direction. The insulating film CR may be formed of an insulating material, such as silicon oxide. The semiconductor film CH extends in the Z direction so as to cover the insulating film CR from the outside in the XY directions and has a cylindrical shape having an axis along the Z direction. The semiconductor film CH may be formed of a semiconductor, such as polysilicon. The insulating film TNL extends in the Z direction so as to cover the semiconductor film CH from the outside in the XY directions and has a cylindrical shape having an axis along the Z direction. The insulating film TNL may be formed of an insulating material, such as silicon oxide. The charge storage film CT extends in the Z direction so as to cover the insulating film TNL from the outside in the XY directions and has a cylindrical shape having an axis along the Z direction. The charge storage film CT may be formed of an insulating material, such as silicon nitride. The insulating film BLK1 extends in the Z direction so as to cover the charge storage film CT from the outside in the XY directions and has a cylindrical shape having an axis along the Z direction. The insulating film BLK1 may be formed of an insulating material, such as silicon oxide. The insulating film BLK2 extends in the Z direction so as to cover the insulating film BLK1 from the outside in the XY directions and has a cylindrical shape having an axis along the Z direction. The insulating film BLK2 may be formed of an insulating material, such as aluminum oxide. Portions surrounded by dotted lines in FIGS. 6A and 6B function as the memory cells MT.

As illustrated in FIG. 4, the semiconductor film CH in the columnar body CL has an end on the +Z side connected to the conductive layer 7 and has another end on the −Z side connected to the conductive film BL through a plug. The conductive film BL functions as the bit line BL (see FIG. 2). The conductive layer 7 may be formed of a semiconductor (for example, polysilicon) imparted with conductivity. A conductor 8 is disposed on the +Z side of the conductive layer 7. The conductor 8 has a projection portion extending in the −Z direction, and the end on the −Z side of the projection portion is in contact with the conductive layer 7. The conductor 8 extends in the XY directions from a region overlapping the conductive layer 52 to the outside thereof when viewed in the Z direction. The conductor 8 is connected to the plug CC on the −Z side outside the region overlapping the conductive layer 52. The conductive layer 7 functions as a cell source portion CSL in the source line SL (see FIG. 2). The conductor 8 functions as another portion of the source line SL. The semiconductor film CH functions as a channel region in the memory string MS (see FIG. 2).

Further, the respective conductive layers 5 may have the same width in the Y direction. The plurality of conductive layers 5 each have a width in the X direction increasing stepwise from the −Z side to the +Z side. The plurality of conductive layers 5 locate ends in the X direction gradually outward from the −Z side to the +Z side. Thereby, a stepwise structure is formed in which the select gate line SGD, the plurality of word lines WL0 to WL5, and the select gate line SGS are pulled out stepwise and sequentially from the −Z side to the +Z side at a plug connection portion in the memory cell array 11_1.

The plurality of plugs CC extend in the Z direction. The plug CC may have an end on the −Z side electrically connected to the electrode PD4, extend in the Z direction, and have another end on the +Z side connected to the conductive layer 5. Thereby, the conductive layer 5 may be connected to the transistor Tr of the chip 10 via the plug CC, the electrode PD4, the electrode PD3, the plug CC, the electrode PD2, the electrode PD1, and the wiring structure WS.

The plurality of conductive films BL are disposed on the −Z side of the stacked body SST2. The plurality of conductive films BL are arranged in the X direction with each other. Each conductive film BL extends in the Y direction. The plurality of conductive films BL correspond to the plurality of columnar bodies CL. Each conductive film BL is electrically connected to the end on the −Z side of the corresponding columnar body CL and functions as the bit line BL. The conductive film BL is electrically connected to the electrode PD4. Thereby, the bit line BL may be connected to the transistor Tr of the chip 10 via the electrode PD4, the electrode PD3, the plug CC, the electrode PD2, the electrode PD1, and the wiring structure WS.

The electrode PD4 exposes a surface thereof to the bonding surface BF1 between the chip 20_1 and the chip 20_2, as described above.

The chip 30 includes an electrode BP, a plurality of line patterns SP-1 to SP-4, a plurality of conductive films LP, a plurality of plugs CC, and an insulating film DL4.

The electrode BP is disposed at a position not overlapping the stacked bodies SST1 and SST2 when viewed in the Z direction. A surface on the +Z side of the electrode BP is exposed in an opening OP, and a surface on the −Z side of the electrode BP is connected to the plug CC. A wire for wire bonding is bonded to the surface on the +Z side of the electrode BP.

The plurality of conductive films LP are disposed on the +Z side of the plurality of line patterns SP-1 to SP-4. The plurality of conductive films LP are disposed at Z positions (depths) that are the same as the positions of the electrodes BP. The plurality of conductive films LP are aligned with each other in the X direction. Each conductive film LP extends in the Y direction. Each conductive film LP is, for example, a pattern that functions as the power supply lines 31 and 32 (see FIG. 1). Although FIGS. 3 to 5 illustrate a configuration in which the number of conductive films LP is six, the number of conductive films LP may be two to five or may be seven or more.

The plurality of line patterns SP-1 to SP-4 are disposed at positions overlapping the stacked bodies SST1 and SST2 when viewed in the Z direction. The plurality of line patterns SP-1 to SP-4 are disposed at positions that do not overlap the electrodes BP when viewed in the Z direction. The plurality of line patterns SP-1 to SP-4 are aligned with each other in the Y direction. Each line pattern SP extends in the X direction. Each line pattern SP is a pattern for flatly supporting the other chips 20_1 and 20_2. Each line pattern SP has greater rigidity in the X direction than rigidity in the Y direction. Thereby, when the other chips 20_1 and 20_2 are warped in the X direction but hardly along the Y direction, a warpage in the X direction of each line pattern SP in the other chips 20_1 and 20_2 may be selectively corrected. Although FIGS. 3 to 5 illustrate a configuration in which the number of line patterns SP is four, the number of line patterns SP may be two to three or may be five or more.

A width in the Y direction of each line pattern SP is greater than a width in the X-direction of the conductive film LP. A length in the X direction length of each line pattern SP is greater than a length in the Y direction of the conductive film LP. A thickness in the Z direction of each line pattern SP is greater than a thickness in the Z direction of the conductive film LP.

The width in the Y direction of each line pattern SP is greater than a width in the X direction of the conductive film BL of the chip 20_1 and greater than a width in the X direction of the conductive film BL of the chip 20_2. The length in the X direction of each line pattern SP is greater than a length in the Y direction of the conductive film BL of the chip 20_1 and greater than a length in the Y direction of the conductive film BL of the chip 20_2. The thickness in the Z direction of each line pattern SP is greater than a thickness in the Z direction of the conductive film BL of the chip 20_1 and greater than a thickness in the Z direction of the conductive film BL of the chip 20_2.

The width in the Y direction of each line pattern SP is greater than a width in the Y direction of the conductive layer 5 of the chip 20_1 and greater than a width in the Y direction of the conductive layer 5 of the chip 20_2. The length in the X direction of each line pattern SP is greater than a length in the X direction of the conductive layer 5 of the chip 20_1 and greater than a length in the X direction of the conductive layer 5 of the chip 20_2. The thickness in the Z direction of each line pattern SP is greater than a thickness in the Z direction of the conductive layer 5 of the chip 20_1 and greater than a thickness in the Z direction of the conductive layer 5 of the chip 20_2.

The width in the Y direction of each line pattern SP is greater than a width in the Y direction of the conductive layer 7 of the chip 20_1 and greater than a width in the Y direction of the conductive layer 7 of the chip 20_2. The length in the X direction of each line pattern SP is greater than a length in the X direction of the conductive layer 7 of the chip 20_1 and greater than a length in the X direction of the conductive layer 7 of the chip 20_2. The thickness in the Z direction of each line pattern SP is greater than a thickness in the Z direction of the conductive layer 7 of the chip 20_1 and greater than a thickness in the Z direction of the conductive layer 7 of the chip 20_2.

The plurality of plugs CC extend in the Z direction. The plug CC may have an end on the −Z side electrically connected to the conductive film LP, extend in the Z direction, and have an end on the +Z side connected to the plug CC of the chip 20_2. Thereby, the conductive film LP may be connected to the transistor Tr of the chip 10 via the plug CC, the plug CC, the electrode PD4, the electrode PD3, the plug CC, the electrode PD2, the electrode PD1, and the wiring structure WS. Thereby, the plug CC may transmit power supply voltages and the like between the chip 30 and the chip 20_2. The plug CC may have an end on the −Z side electrically connected to the electrode BP, extend in the Z direction, and have another end on the +Z side connected to the plug CC of the chip 20_2. Thereby, the electrode BP may be connected to the transistor Tr of the chip 10 via the plug CC, the plug CC, the electrode PD4, the electrode PD3, the plug CC, the electrode PD2, the electrode PD1, and the wiring structure WS. Thereby, the plug CC may transmit signals and the like between the chip 30 and the chip 20_2.

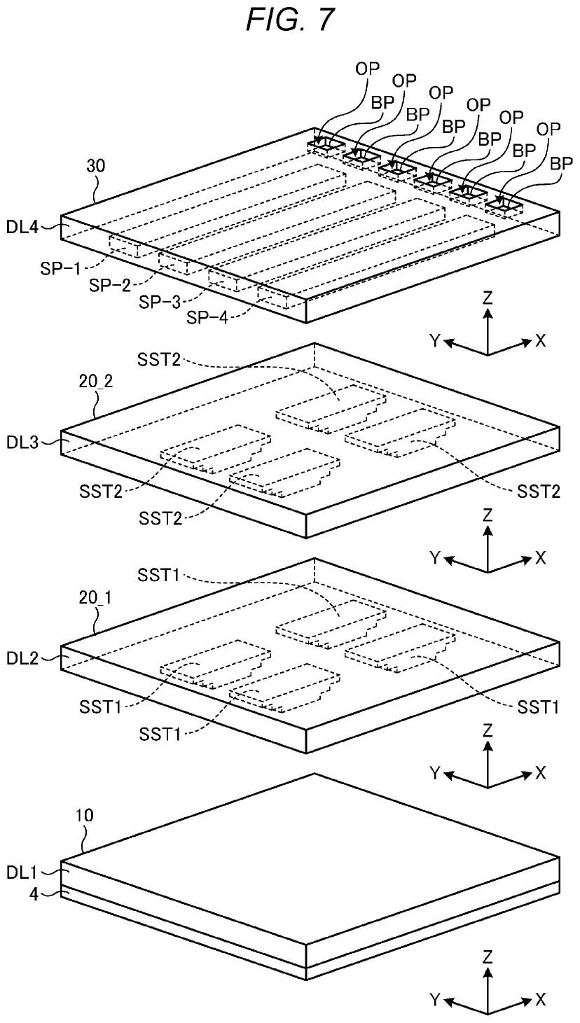

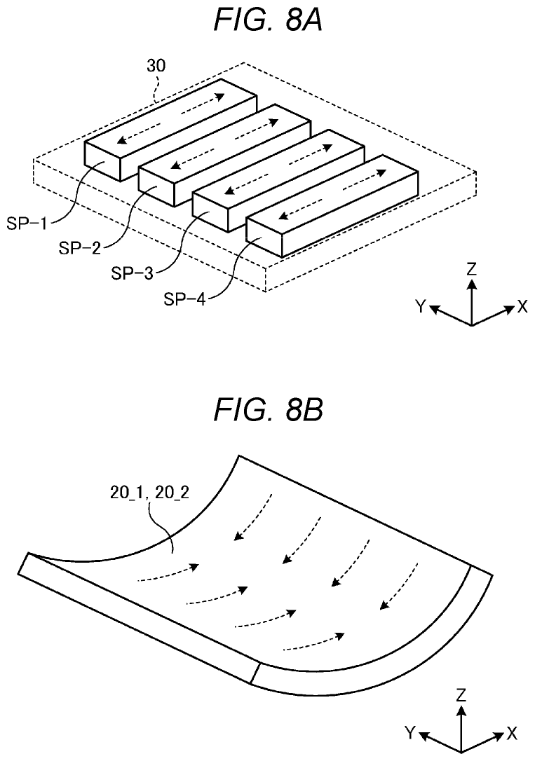

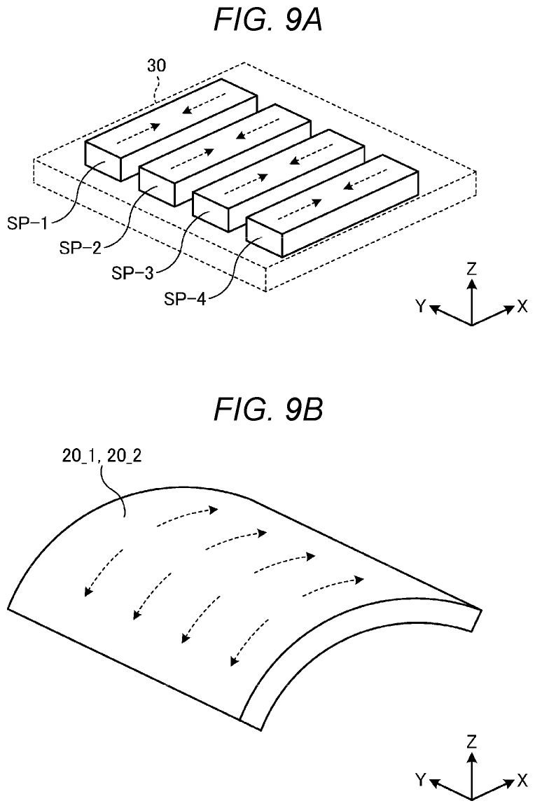

FIG. 7 is an exploded perspective view illustrating a configuration of the semiconductor memory device 1 and illustrates a state where the configuration of the semiconductor memory device 1 is disassembled in a chip unit. FIG. 8 is a view illustrating a function of the chip (support chip) 30 when the chip (array chip) 20 may warp convexly on the −Z side. FIG. 9 is a view illustrating a function of the chip (support chip) 30 when the chip (array chip) 20 may warp convexly on the +Z side.

As illustrated in FIG. 7, the chips 10, 20_1, 20_2, and 30 are sequentially stacked from the −Z side to the +Z side in the semiconductor memory device 1.

The plurality of stacked bodies SST1 are disposed in the chip 20_1. Each stacked body SST1 has a structure in which layers with different coefficients of thermal expansion are alternately stacked a plurality of times with the X direction as a longitudinal direction. The stacked body SST1 is easily stressed due to a difference in coefficient of thermal expansion between a plurality of layers due to heat treatment or the like during a manufacturing process. The stacked body SST1 has a width in the X direction on the +Z side greater than a width in the X direction on the −Z side.

For example, when a tensile stress acts in the X direction near the surface on the +Z side in the chip 20_1 as indicated by dotted arrows in FIG. 8B, a warpage in the Y direction hardly occurs, and a warpage in the X direction may occur. The chip 20_1 is relatively flat when viewed in a YZ cross section but may warp convexly toward the −Z side when viewed in an XZ cross section.

As illustrated in FIG. 7, the plurality of stacked bodies SST2 are disposed in the chip 20_2. Each stacked body SST2 has a structure in which layers having different coefficients of thermal expansion are alternately stacked a plurality of times, with the X direction as a longitudinal direction. The stacked body SST2 is easily stressed due to a difference in coefficient of thermal expansion between a plurality of layers due to heat treatment or the like during a manufacturing process. The stacked body SST2 has a width in the X direction on the +Z side greater than a width in the X direction on the −Z side.

For example, when a tensile stress acts in the X direction near the surface on the +Z side in the chip 20_2 as indicated by dotted arrows in FIG. 8B, a warpage in the Y direction hardly occurs, and a warpage in the X direction may occur. The chip 20_2 is relatively flat when viewed in a YZ cross section but may warp convexly toward the −Z side when viewed in an XZ cross section.

In contrast to this, a plurality of line patterns SP are disposed in the chip 30 as illustrated in FIG. 7. Each line pattern SP extends in the X direction and has greater rigidity in the X direction than rigidity in the Y direction. Each line pattern SP may have a compressive stress as indicated by dotted arrows in FIG. 8A. Each line pattern SP may have a compressive stress by being formed of a silicon oxide formed under the first film-forming condition, polysilicon, a silicon nitride formed under the second film-forming condition, or the like. The first film-forming condition is a condition in which a film density is higher than a film-forming condition of the insulating film DL4.

When the silicon oxide formed under the first film-forming condition is selected as a material of each line pattern SP, a film density of each line pattern SP is higher than a film density of the surrounding insulating film DL4. When polysilicon, a silicon nitride formed under the second film-forming condition, or the like is selected as a material of each line pattern SP, a composition of each line pattern SP differs from a composition of the surrounding insulating film DL4.

When each line pattern SP has a compressive stress, the chip 30 may be stressed in a direction of flattening again the warpage by being bonded to the chips 20_1 and 20_2. That is, the chip 30 may correct the warpages of the chips 20_1 and 20_2.

Alternatively, when a compressive stress acts in the X direction near a surface on the +Z side in the chip 20_1 as indicated by dotted arrows in FIG. 9B, a warpage in the Y direction hardly occurs, and a warpage in the X direction may occur. The chip 20_1 is relatively flat when viewed in the YZ cross section, but may warp convexly toward the +Z side when viewed in the XZ cross section.

For example, when a compressive stress acts in the X direction near a surface on the +Z side in the chip 20_2 as indicated by dotted arrows in FIG. 9B, a warpage in the Y direction hardly occurs, and a warpage in the X direction may occur. The chip 20_2 is relatively flat when viewed in the YZ cross section but may warp convexly toward the +Z side when viewed in the XZ cross section.

In contrast to this, each line pattern SP in the chip 30 may have a tensile stress as indicated by dotted arrows in FIG. 9A. Each line pattern SP may have a tensile stress by being formed of tungsten, titanium, aluminum oxide, polysilicon obtained by heat-treating amorphous silicon, a silicon nitride formed under the third film-forming condition, or the like. The third film-forming condition is a film-forming condition in which a film density of a silicon nitride is lower than the second film-forming condition.

When tungsten, titanium, aluminum oxide, polysilicon obtained by heat-treating amorphous silicon, or a silicon nitride formed under the third film-forming condition is selected as a material of each line pattern SP, a composition of each line pattern SP differs from a composition of the surrounding insulating film DL4.

When each line pattern SP has a tensile stress, the chip 30 may be stressed in a direction of flattening again the warpage by being bonded to the chips 20_1 and 20_2. That is, the chip 30 may correct the warpages of the chips 20_1 and 20_2.

As described above, in the semiconductor memory device 1 according to the embodiment, the chip 30 includes a plurality of line patterns SP-1 to SP-4. Each of the line patterns SP-1 to SP-4 extends along directions of warpages of the chips 20_1 and 20_2. Thereby, as the chip 30 is bonded to the chips 20_1 and 20_2, the warpages of the chips 20_1 and 20_2 may be corrected to flatten the chips 20_1 and 20_2. As a result, bonding positions of the chips 10, 20_1, and 20_2 can be easily optimized during bonding, and the bonding misalignment and defective bonding of the electrodes PD1 to PD4 can be reduced. That is, the plurality of chips 10, 20_1, and 20_2 may be appropriately bonded to each other.

Correction of a warpage by the chip (support chip) 30 is not limited to the application to the array chip of the nonvolatile memory exemplified in the embodiment and may be applied to any chip (an array chip of a volatile memory, a logic chip, an imaging sensor chip, and the like) that may be warped as illustrated in FIGS. 8B and 9B. That is, by bonding the chip (support chip) 30 from the +Z side to a chip that may be warped as illustrated in FIGS. 8B and 9B, a semiconductor device of which warpage is corrected can be obtained in the same manner as in the embodiment.

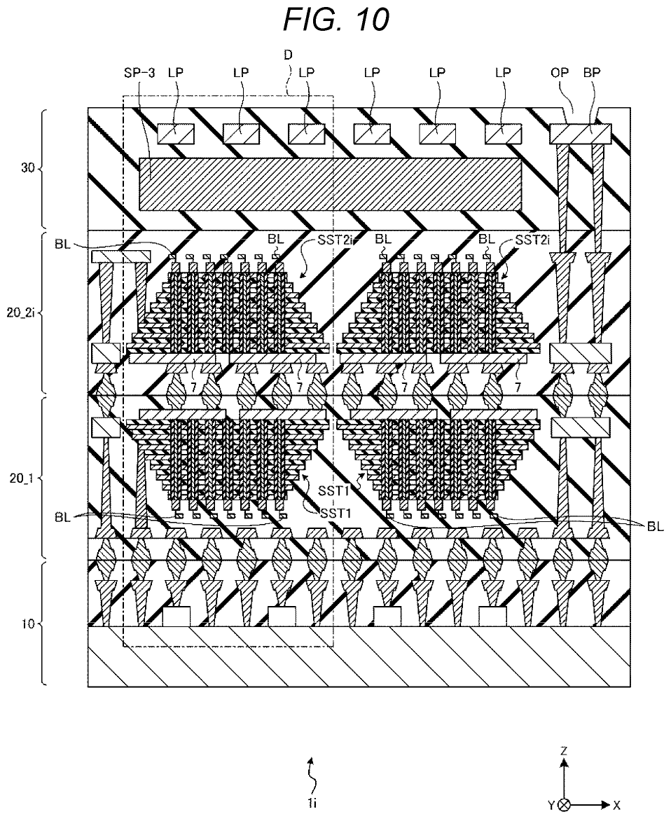

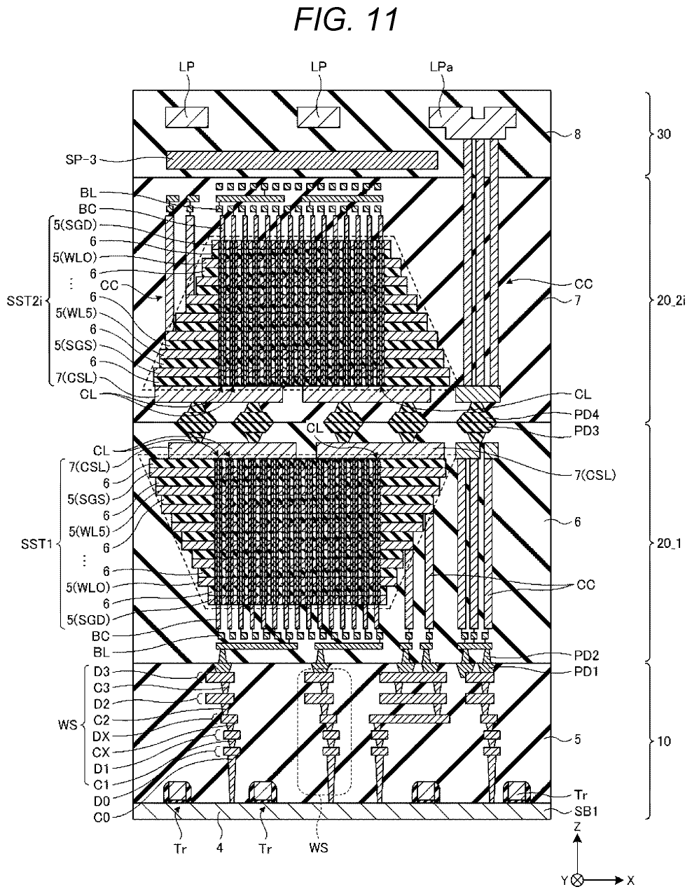

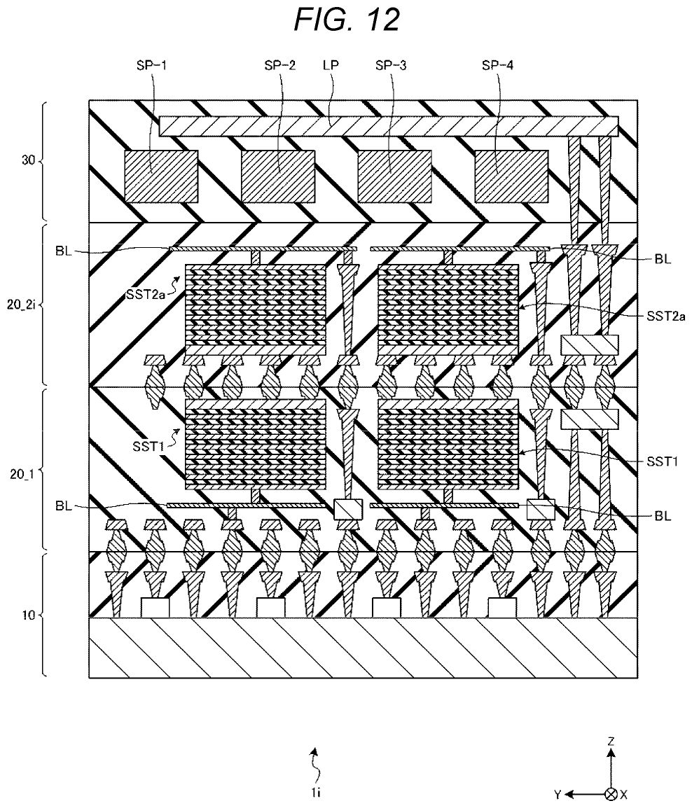

Further, according to a first modification example of the embodiment, as illustrated in FIGS. 10 to 12, orientations of stacked bodies may be different from each other between a plurality of array chips of a semiconductor memory device 1i. FIG. 10 is an XZ cross-sectional view schematically illustrating a configuration of the semiconductor memory device 1i according to the first modification example of the embodiment. FIG. 11 is an XZ cross-sectional view illustrating the configuration of a semiconductor memory device 1i according to the first modification example of the embodiment and is a cross-sectional view illustrating a D portion of FIG. 10 in detail. FIG. 12 is a YZ cross-sectional view schematically illustrating the configuration of the semiconductor memory device 1i according to the first modification example of the embodiment.

In the semiconductor memory device 1i, a stacked body SST1 in a chip (array chip) 20_1 and a stacked body SST2i in a chip (array chip) 20_2i are oriented differently. The orientation of the stacked body SST1 and the orientation of the stacked body SST2i are opposite to each other in the Z direction.

The chip 20_2i has the stacked body SST2i instead of the stacked body SST2 (see FIGS. 3 to 5). The stacked body SST2i has a substantially isosceles trapezoidal shape in an XZ cross-sectional view and has a substantially rectangular shape in a YZ cross-sectional view. In the substantially isosceles trapezoidal shape, a lower base is longer than an upper base. A conductive layer 7 is disposed on the −Z side of the stacked body SST2i. A plurality of conductive films BL are disposed on the +Z side of the stacked body SST2i. As illustrated in FIG. 11, a semiconductor film CH (see FIGS. 6A and 6B) in a columnar body CL has an end on the −Z side connected to the conductive layer 7 and has an end on the +Z side connected to a conductive film BL through a plug.

Further, the respective conductive layers 5 may have the same width in the Y direction. A plurality of conductive layers 5 have a width in the X direction increasing stepwise from the +Z side to the −Z side. The plurality of conductive layers 5 locates the ends in the X direction gradually outward from the +Z side to the −Z side. Thereby, a stepwise structure is formed in which a select gate line SGD, a plurality of word lines WL0 to WL5, and a select gate line SGS are pulled out stepwise and sequentially from the +Z side to the −Z side at a plug connection portion in a memory cell array 11_2.

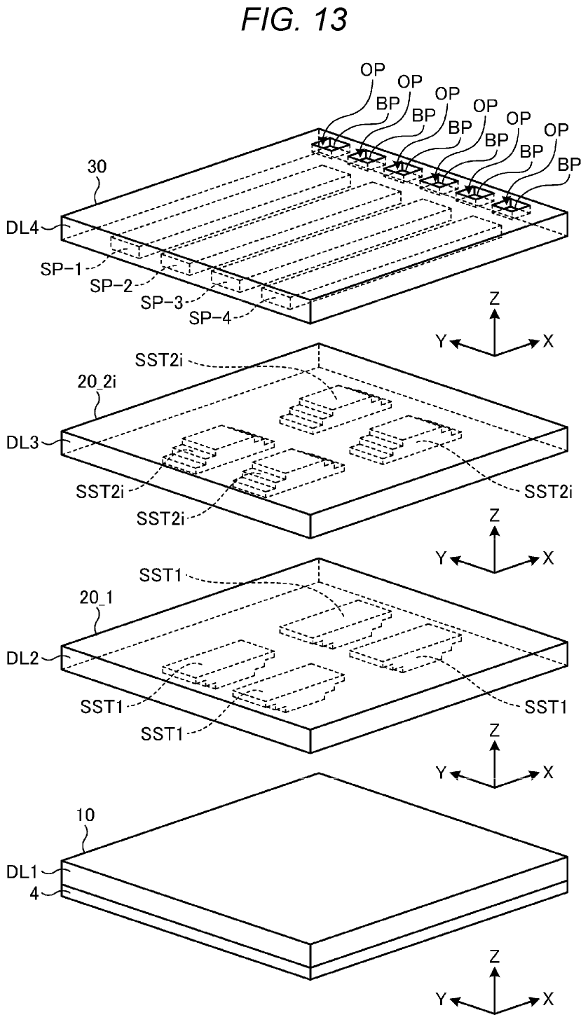

In the semiconductor memory device 1i, as illustrated in FIG. 13, the orientation of the stacked body SST1 in the chip 20_1 and the orientation of the stacked body SST2i in the chip 20_2i are opposite to each other in the Z direction. The stacked body SST1 has a width in the X direction on the +Z side greater than a width in the X direction on the −Z side. The stacked body SST2i has a width in the X direction on the +Z side less than a width in the X direction on the −Z side. Accordingly, an orientation of a warpage that may occur in the chip 20_1 may be opposite to an orientation of a warpage that may occur in the chip 20_2i.

In this case, in a state where the chip 20_1 and the chip 20_2i are bonded together, when a tensile stress acts in the X direction near a surface on the +Z side of the chip 20_2i as indicated by the dotted arrows in FIG. 8B, the chip (support chip) 30 may be configured as illustrated in FIG. 8A. That is, in the chip 30, each line pattern SP extends in the X direction, and the rigidity in the X direction is greater than the rigidity in the Y direction. Each line pattern SP is formed of a silicon oxide formed under a condition that a film density is higher than a film density of the insulating film DL4, polysilicon, a silicon nitride formed under a second film-forming condition, or the like. Thereby, each line pattern SP may have a compressive stress in the X direction, as indicated by the dotted arrows in FIG. 8A.

Alternatively, in a state where the chip 20_1 and the chip 20_2i are bonded together, when a compressive stress acts in the X direction near a surface on the +Z side of the chip 20_2 as indicated by the dotted arrows in FIG. 9B, a chip (support chip) 30 may be configured as illustrated in FIG. 9A. That is, in the chip 30, each line pattern SP extends in the X direction, and the rigidity in the X direction is greater than the rigidity in the Y direction. Each line pattern SP may have a tensile stress by being formed of tungsten, titanium, aluminum oxide, polysilicon obtained by heat-treating amorphous silicon, a silicon nitride formed under the third film-forming condition, or the like. The third film-forming condition is a film-forming condition in which a film density of a silicon nitride is lower than the second film-forming condition. Thereby, each line pattern SP may have a tensile stress in the X direction, as indicated by the dotted arrows in FIG. 9A.

Thus, in the semiconductor memory device 1i, each of line patterns SP-1 to SP-4 in the chip 30 extends along a combined warpage direction of the chips 20_1 and 20_2i. Each of the line patterns SP-1 to SP-4 may have a stress according to the combined warpage of the chips 20_1 and 20_2i. Thereby, as the chip 30 is bonded to the chips 20_1 and 20_2, the warpages of the chips 20_1 and 20_2 may be corrected to flatten the chips 20_1 and 20_2.

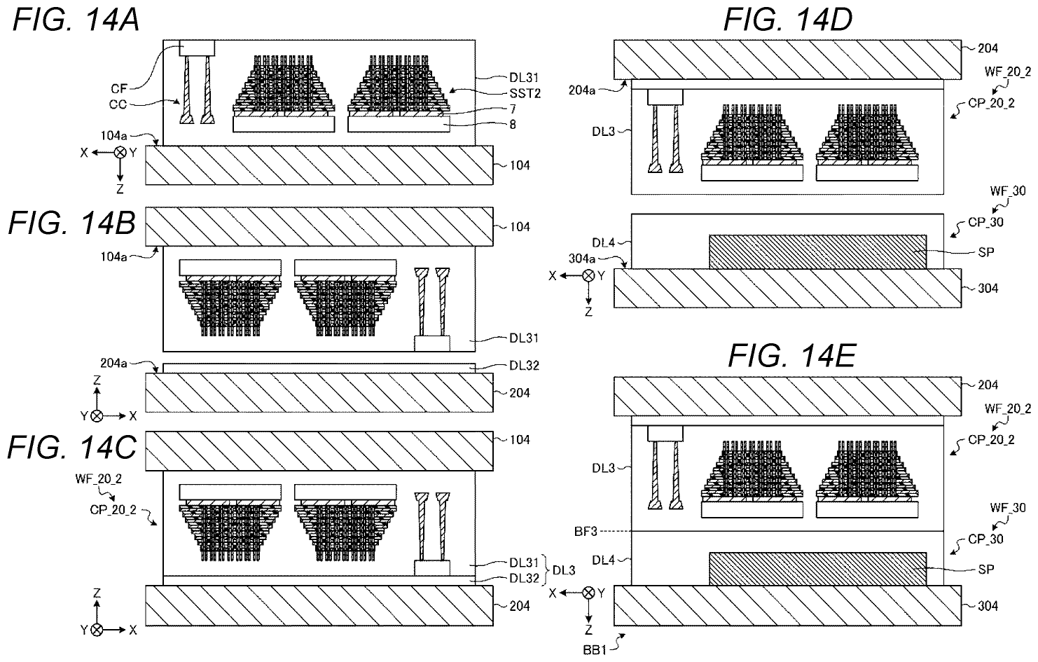

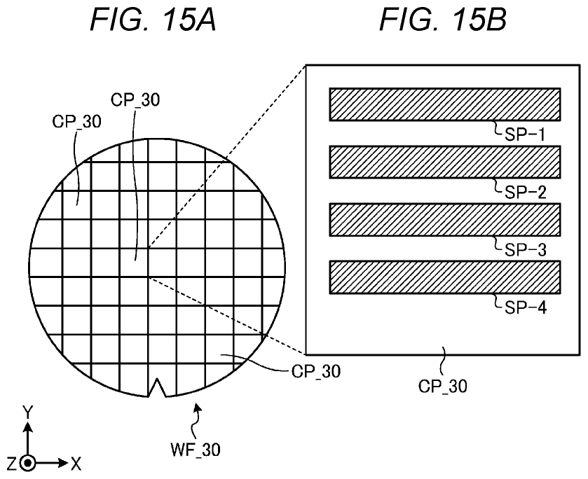

Further, as a second modification example of the embodiment, the semiconductor memory device 1 (see FIGS. 3-5) may be manufactured as illustrated in FIGS. 14 to 18B. FIGS. 14A to 14E, FIGS. 16A to 16C, FIGS. 17A to 17C, and FIGS. 18A and 18B are XZ cross-sectional views illustrating a method of manufacturing the semiconductor memory device 1. FIGS. 15A and 15B are XY plan views illustrating patterns in each chip region of a supporting substrate.

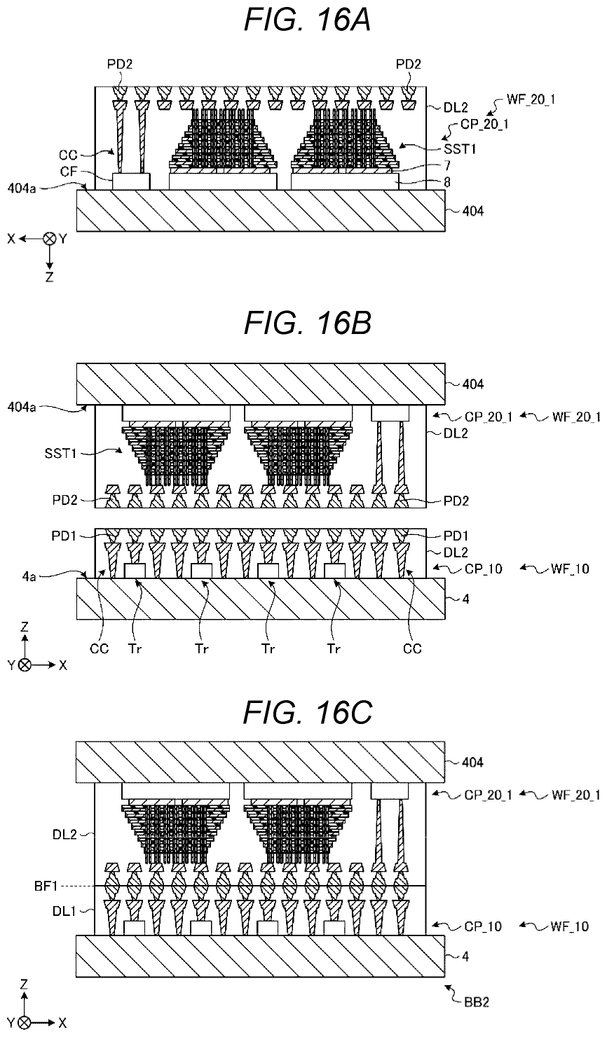

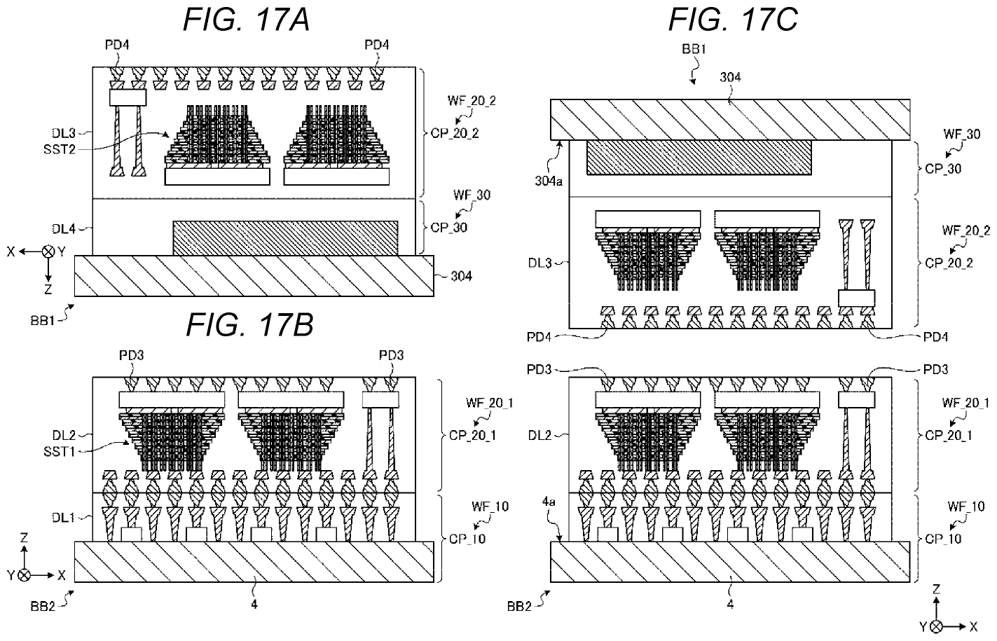

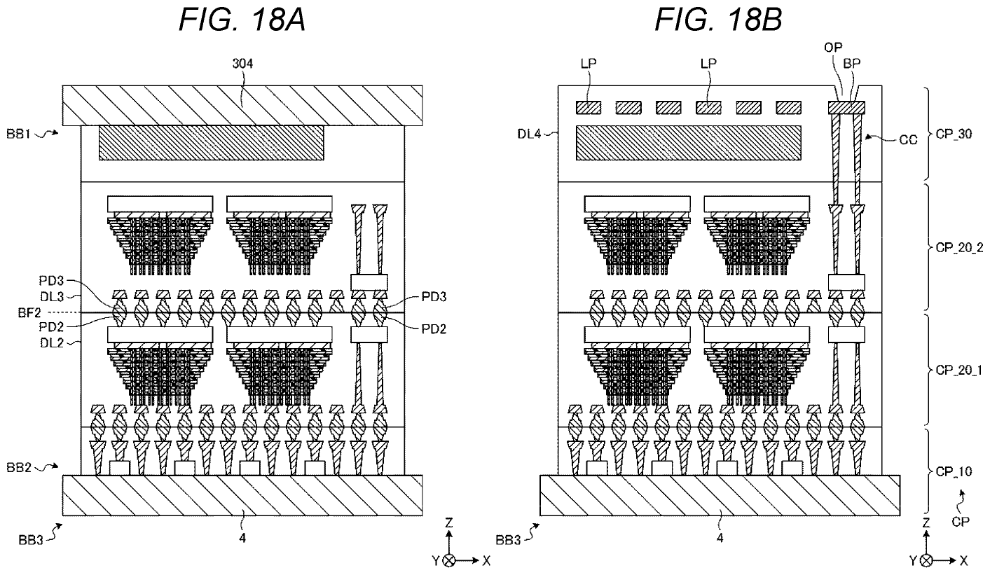

In the method of manufacturing the semiconductor memory device 1, steps illustrated in FIGS. 14A to 14E and steps illustrated in FIGS. 16A to 16C are performed in parallel, and thereafter, steps illustrated in FIGS. 17A to 17C and FIGS. 18A and 18B are performed. The respective steps are actually performed by using a substrate WF on which a plurality of chip regions CP are mounted, as illustrated in FIG. 15A. For the sake of simplification, each XZ cross-sectional view illustrates a cross section of the substrate WF on which one chip region CP is mounted.

In a step illustrated in FIG. 14A, a substrate 104 is prepared. The substrate 104 may be formed of a material with a semiconductor (for example, silicon) as a main component. The substrate 104 has a main surface 104a on the −Z side.

After an insulating film is deposited on the main surface 104a of the substrate 104, a conductive film is deposited and patterned to form a conductive layer 8. The conductive layer 8 may be formed of a material with a metal such as aluminum as a main component. Thereafter, a conductive film is deposited and patterned to form a conductive layer 7. The conductive layer 7 may be formed of a semiconductor such as polysilicon. Thereafter, the insulating layer 6 (see FIG. 4) and a sacrificial layer (not illustrated) are alternately deposited a plurality of times on the −Z side of the conductive layer 7 to form a stacked body SST2a. The insulating layer 6 may each be formed of an insulating material, such as silicon oxide. The sacrificial layer may be formed of an insulating material such as a silicon nitride that may ensure etching selectivity with respect to the insulating layer 6. Each insulating layer 6 and each sacrificial layer may be deposited with approximately the same film thickness.

A patterned resist in which a formation position of a division film is opened in a line shape extending in the X direction is formed on the insulating layer 6 closest to the −Z side. When the patterned resist is formed, an exposure processing of the substrate 104 is performed, but the substrate 104 is heat-treated before and/or after the exposure processing. Anisotropic etching such as reactive ion etching (RIE) is performed by using the patterned resist as a mask to form a groove penetrating the stacked body SST2a in the XZ direction. Then, a division film SLT is embedded in the groove. The division film SLT may be formed of a material with an insulating material (for example, a silicon oxide) as a main component. The division film SLT extends in the XZ direction and divides the stacked body SST2a in the Y direction. The division film SLT is divided into a stacked body SST2 on the −Y side and a stacked body SST2 on the +Y side. In each stacked body SST2, the insulating layer 6 and each sacrificial layer are alternately stacked a plurality of times.

A patterned resist in which a formation position of a memory hole MH is opened is formed on the −Z side of the insulating layer 6 closest to the −Z side of each stacked body SST2 and on the −Z side of the division film SLT. When the patterned resist is formed, an exposure processing of the substrate 104 is performed, but the substrate 104 is heat-treated before and/or after the exposure processing. Anisotropic etching such as RIE is performed by using the patterned resist as a mask to form a memory hole MH that reaches the conductive layer 7 by penetrating the division film SLT and the stacked body SST2.

An insulating film BLK2, an insulating film BLK1, and an insulating film TNL (see FIG. 6) are sequentially deposited on a side surface and a bottom surface of the memory hole MH. The insulating film BLK2 may be formed of an insulating material, such as aluminum oxide. The insulating film BLK1 may be formed of an insulating material, such as silicon oxide. The bottom surface of the memory hole MH in the insulating film TNL is selectively removed.

The semiconductor film CH (see FIG. 6) is deposited on the side surface and the bottom surface of the memory hole MH. The semiconductor film CH may be formed of a material with a semiconductor (for example, polysilicon) that does not substantially contain impurities as a main component. Then, a core member CR (see FIG. 6) is embedded in the memory hole MH. The core member CR may be formed of an insulating material such as a silicon oxide. Thereby, the columnar body CL penetrating the stacked body SST2 in the Z direction is formed.

The sacrificial layer of the stacked body SST2 is removed. The conductive layer 5 (see FIG. 4) is embedded in a void formed by the removal. The conductive layer 5 may be formed of a material with a conductive material (for example, a metal such as tungsten) as a main component. Thereby, a stacked body SST2 in which the conductive layer 5 and the insulating layer 6 are stacked alternately and repeatedly is formed.

Further, an insulating film DL31 is deposited, and a hole is formed at a position shifted in the XY directions from the stacked body SST2 in an insulating film DL31. A plug CC is formed by embedding a conductive material (for example, a material with copper or the like as a main component) in the hole. Furthermore, a conductive film is deposited on the −Z side of the plug CC and patterned. Thereby, a conductive film CF is formed.

In a step illustrated in FIG. 14B, a substrate 204 is prepared. The substrate 204 may be a semiconductor substrate and may be formed of a material with a semiconductor (for example, silicon) as a main component. The substrate 204 has a main surface 204a on the +Z side.

An insulating film DL32 is deposited on the main surface 204a of the substrate 204. Thereafter, a surface on the −Z side of the insulating film DL31 and a surface on the +Z side of the insulating film DL32 may be activated by plasma irradiation or the like. The substrate 104 and the substrate 204 are disposed such that the main surface 104a and the main surface 204a face each other.

In a step illustrated in FIG. 14C, the substrate 104 and the substrate 204 are brought close to each other in the Z direction, and the surface on the −Z side of the insulating film DL31 is bonded to the surface on the +Z side of the insulating film DL32. At this time, the substrates 104 and 204 may be heated and pressurized. Thereby, the insulating film DL3 including the insulating film DL31 and the insulating film DL32 is formed. That is, a structure of a substrate (array substrate) WF_20_2 including a chip region CP_20_2 corresponding to the chip 20_2 is formed.

Thereafter, the substrate 104 is removed. Removal of the substrate 104 may be performed by polishing the substrate 104 from the +Z side.

In a step illustrated in FIG. 14D, a substrate 304 is prepared. The substrate 304 may be a semiconductor substrate and may be formed of a material with a semiconductor (for example, silicon) as a main component. The substrate 304 has a main surface 304a on the −Z side.

A film of a material to become the line patterns SP is deposited on the main surface 304a of the substrate 304, and the film is patterned to form a plurality of line patterns SP-1 to SP-4. The material to become the line patterns SP and a direction in which the line patterns SP extend may be determined according to a warpage that may occur in the chip region CP_20_2. thereafter, the insulating film DL4 is deposited.

For example, in the chip region CP_20_2, when a tensile stress acts in the X direction near a surface on the +Z side, a warpage hardly occurs in the Y direction and may occur in the X direction as indicated by the dotted arrows in FIG. 8B. The chip 20_2 is relatively flat when viewed in a YZ cross section but may warp convexly toward the −Z side when viewed in an XZ cross section.

In this case, a material having a compressive stress indicated by the dotted arrows in FIG. 8A may be selected as the material to become the line patterns SP. Each line pattern SP may have a compressive stress by being formed of a silicon oxide formed under the first film-forming condition, polysilicon, a silicon nitride formed under the second film-forming condition, or the like. The first film-forming condition is a condition in which a film density is higher than a film-forming condition of the insulating film DL4. Further, each line pattern SP is patterned to extend in the X direction, as illustrated in FIG. 15B. The plurality of line patterns SP-1 to SP-4 may be arranged in the Y direction.

Alternatively, when a compressive stress acts in the X direction near a surface on the +Z side in the chip 20_1 as indicated by dotted arrows in FIG. 9B, a warpage in the Y direction hardly occurs, and a warpage in the X direction may occur. The chip 20_1 is relatively flat when viewed in the YZ cross section, but may warp convexly toward the +Z side when viewed in the XZ cross section.

In this case, a material having a tensile stress indicated by the dotted arrows in FIG. 9A may be selected as the material to become the line patterns SP. Each line pattern SP may have a tensile stress by being formed of tungsten, titanium, aluminum oxide, polysilicon obtained by heat-treating amorphous silicon, a silicon nitride formed under the third film-forming condition, or the like. The third film-forming condition is a film-forming condition in which a film density of a silicon nitride is lower than the second film-forming condition. Further, each line pattern SP is patterned to extend in the X direction, as illustrated in FIG. 15B. The plurality of line patterns SP-1 to SP-4 may be arranged in the Y direction.

Thereby, a structure of a substrate (supporting substrate) WF_30 including a chip region CP_30 corresponding to the chip 30 is formed.

Thereafter, a surface on the +Z side of the insulating film DL3 and a surface on the −Z side of the insulating film DL4 may be activated by plasma irradiation or the like. The substrates 204 and 304 are disposed such that the main surface 204a and the main surface 304a face each other.

In a step illustrated in FIG. 14E, the substrate 204 and the substrate 304 are brought close to each other in the Z direction, and the surface on the +Z side of the insulating film DL3 is bonded to the surface on the −Z side of the insulating film DL4. At this time, the substrates 204 and 304 may be heated and pressurized. Thereby, a bonded body BB1 is obtained in which the substrate WF_20_2 including the chip region CP_20_2 and the substrate WF_30 including the chip region CP_30 are bonded together at the bonding surface BF3.

Thereafter, the substrate 204 is removed. The removal of the substrate 204 may be performed by polishing the substrate 204 from the −Z side.

Meanwhile, in a step illustrated in FIG. 16A, a substrate 404 is prepared. The substrate 404 may be a semiconductor substrate and may be formed of a material with a semiconductor (for example, silicon) as a main component. The substrate 404 has a main surface 404a on the −Z side.

After an insulating film is deposited on the main surface 404a of the substrate 404, a conductive film is deposited and patterned to form the conductive layer 8. The conductive layer 8 may be formed of a material with a metal such as aluminum as a main component. Thereafter, a conductive film is deposited and patterned to form a conductive layer 7. The conductive layer 7 may be formed of a semiconductor such as polysilicon. Thereafter, the insulating layer 6 and a sacrificial layer (not illustrated) are alternately deposited a plurality of times on the −Z side of the conductive layer 7 to form a stacked body SST1a. The insulating layer 6 may each be formed of an insulating material, such as silicon oxide. The sacrificial layer may be formed of an insulating material such as a silicon nitride that may ensure etching selectivity with respect to the insulating layer 6. Each insulating layer 6 and each sacrificial layer may be deposited with approximately the same film thickness.

A patterned resist in which a formation position of a division film is opened in a line shape extending in the X direction is formed on the insulating layer 6 closest to the −Z side. When the patterned resist is formed, an exposure processing for the substrate 404 is performed. The substrate 404 is heat-treated before and/or after the exposure processing. Anisotropic etching such as RIE is performed by using the patterned resist as a mask to form a groove penetrating the SST1a in the XZ direction. Then, a division film SLT is embedded in the groove. The division film SLT may be formed of a material with an insulating material (for example, a silicon oxide) as a main component. The division film SLT extends in the XZ direction in the stacked body SST1a and divides the stacked body SST1a in the Y direction. The division film SLT is divided into a stacked body SST1 on the −Y side and a stacked body SST1 on the +Y side. In each stacked body SST1, the insulating layer 6 and each sacrificial layer are alternately stacked a plurality of times.

A patterned resist in which a formation position of the memory hole MH is opened is formed on the −Z side of the insulating layer 6 closest to the −Z side of each stacked body SST1 and on the −Z side of the division film SLT. When the patterned resist is formed, an exposure processing for the substrate 404 is performed. The substrate 404 is heat-treated before and/or after the exposure processing. Anisotropic etching such as RIE is performed by using the patterned resist as a mask to form the memory hole MH that reaches the conductive layer 7 by penetrating the division film SLT and the stacked body SST1.

An insulating film BLK2, an insulating film BLK1, and an insulating film TNL are sequentially deposited on a side surface and a bottom surface of the memory hole MH. The insulating film BLK2 may be formed of an insulating material, such as aluminum oxide. The insulating film BLK1 may be formed of an insulating material, such as silicon oxide. The bottom surface of the memory hole MH in the insulating film TNL is selectively removed.

A semiconductor film CH is deposited on the side surface and the bottom surface of the memory hole MH. The semiconductor film CH may be formed of a material with a semiconductor (for example, polysilicon) that does not substantially contain impurities as a main component. Then, a core member CR is embedded in the memory hole MH. The core member CR may be formed of an insulating material such as a silicon oxide. Thereby, a columnar body CL penetrating the stacked body SST1 in the Z direction is formed.

The sacrificial layer of the stacked body SST1 is removed. A conductive layer 5 is embedded in a void formed by the removal. The conductive layer 5 may be formed of a material with a conductive material (for example, a metal such as tungsten) as a main component. Thereby, the stacked body SST1 in which the conductive layers 5 and the insulating layer 6 are alternately and repeatedly stacked is formed.

Further, a conductive film is deposited at a position shifted in the XY directions from the stacked body SST1, and the conductive film is patterned. Thereby, a conductive film CF is formed. An insulating film DL2 is deposited on the +Z side, and a hole is formed in the insulating film DL2. A plug CC is formed by embedding a conductive material (for example, a material with copper or the like as a main component) in the hole. Furthermore, the insulating film DL2 is deposited and the hole is formed in the insulating film DL2. A conductive material (for example, a material containing copper as a main component) is embedded in the hole to form the electrode PD2. Thereby, the structure of a substrate (array substrate) WF_20_1 including a chip region CP_20_1 corresponding to the chip 20_1 is formed.

In a step illustrated in FIG. 16B, a substrate 4 is prepared. The substrate 4 may be formed of a material with a semiconductor (for example, silicon) as a main component. The substrate 4 has a main surface 4a on the −Z side.

A conductive film of a conductor (for example, polysilicon imparted with conductivity) to become a gate electrode of the transistor Tr is deposited on the main surface 4a of the substrate 4 and is patterned to form the gate electrode of the transistor Tr. Thereafter, an insulating film DL1 is deposited, a hole is formed in the insulating film DL1, and a conductive material (for example, a material with tungsten or the like as a main component) is embedded in the hole to form the plug CC. Furthermore, the insulating film DL1 is deposited and a hole is formed in the insulating film DL1. A conductive material (for example, a material with copper as a main component) is embedded in the hole to form the electrode PD1. Thereby, a structure of a substrate (circuit board) WF_10 including a chip region CP_10 corresponding to the chip 10 is formed.

Thereafter, a surface on the −Z side of the insulating film DL2 and a surface on the +Z side of the insulating film DL1 may be activated by plasma irradiation or the like. The substrate 404 and the substrate 4 are disposed such that the main surface 404a and the main surface 4a face each other. At this time, the substrate 404 and the substrate 4 face each other such that an XY position of the electrode PD2 matches an XY position of the electrode PD1.

In a step illustrated in FIG. 16C, the substrate 404 and the substrate 4 are brought close to each other in the Z direction, and the surface on the −Z side of the insulating film DL2 is bonded to the surface on the +Z side of the insulating film DL1. At this time, the substrate 404 and the substrate 4 may be heated and pressurized. Thereby, a bonded body BB2 is obtained in which the substrate WF_20_1 including the chip region CP_20_1 and the substrate WF_10 including the chip region CP_10 are bonded to each other at the bonding surface BF1. At this time, the electrode PD2 is bonded to the electrode PD1.

Thereafter, the substrate 404 is removed. The removal of the substrate 404 may be performed by polishing the substrate 404 from the +Z side.

In a step illustrated in FIG. 17A, an insulating film DL3 is further deposited on the −Z side of the bonded body BB1 obtained in FIG. 14E, and a hole is formed in the insulating film DL3 for each chip region CP_20_2. A conductive material (for example, a material containing copper as a main component) is embedded in the hole to form the electrode PD4. Thereafter, a surface on the −Z side of the bonded body BB1 may be activated by plasma irradiation or the like.

In a step illustrated in FIG. 17B, an insulating film DL2 is further deposited on the +Z side of the bonded body BB2 obtained in FIG. 16C, and a hole is formed in the insulating film DL2 for each chip region CP_20_1. A conductive material (for example, a material containing copper as a main component) is embedded in the hole to form the electrode PD3. Thereafter, a surface on the +Z side of the bonded body BB2 may be activated by plasma irradiation or the like.

In a step illustrated in FIG. 17C, the bonded body BB1 of FIG. 17A and the bonded body BB2 of FIG. 17B are disposed such that the main surface 304a and the main surface 4a face each other. At this time, the bonded body BB1 and the bonded body BB2 face each other such that an XY position of the electrode PD4 match an XY position of the electrode PD3.

In a step illustrated in FIG. 18A, the bonded body BB1 and the bonded body BB2 are brought close to each other in the Z direction, and a surface on the −Z side of the insulating film DL3 is bonded to a surface on the +Z side of the insulating film DL2. At this time, the bonded body BB1 and the bonded body BB2 may be heated and pressurized. Thereby, a bonded body BB3 is obtained in which the bonded body BB1 and the bonded body BB2 are bonded to each other at the bonding surface BF2. At this time, the electrode PD4 is bonded to the electrode PD3.

In a step illustrated in FIG. 18B, the substrate 304 is removed from the bonded body BB3. The removal of the substrate 304 may be performed by polishing the bonded body BB3 from the +Z side. A surface on the +Z side of the insulating film DL4 in the bonded body BB3i is exposed. A hole is formed in the insulating film DL4, and a conductive material (for example, a material containing tungsten as a main component) is embedded in the hole to form the plug CC. A conductive film formed of a conductive material (for example, a material containing aluminum or the like as a main component) is deposited on the insulating film DL4 and is patterned. Thereby, a conductive film LP and an electrode BP are formed. Thereafter, the insulating film DL4 is further deposited, and an opening OP is formed in a region corresponding to the electrode BP. The opening OP exposes a surface on the +Z side of the electrode BP. Thereby, the bonded body BB3 including the plurality of chip regions CP is obtained.

In each chip region CP, the chip regions CP_10, CP_20_1, CP_20_2, and CP_30 are stacked in the Z direction. By dicing the bonded body BB3 at boundaries between the chip regions CP, the plurality of chip regions CP are separated into pieces. Thereby, the semiconductor memory device 1 including the chip regions CP is obtained.

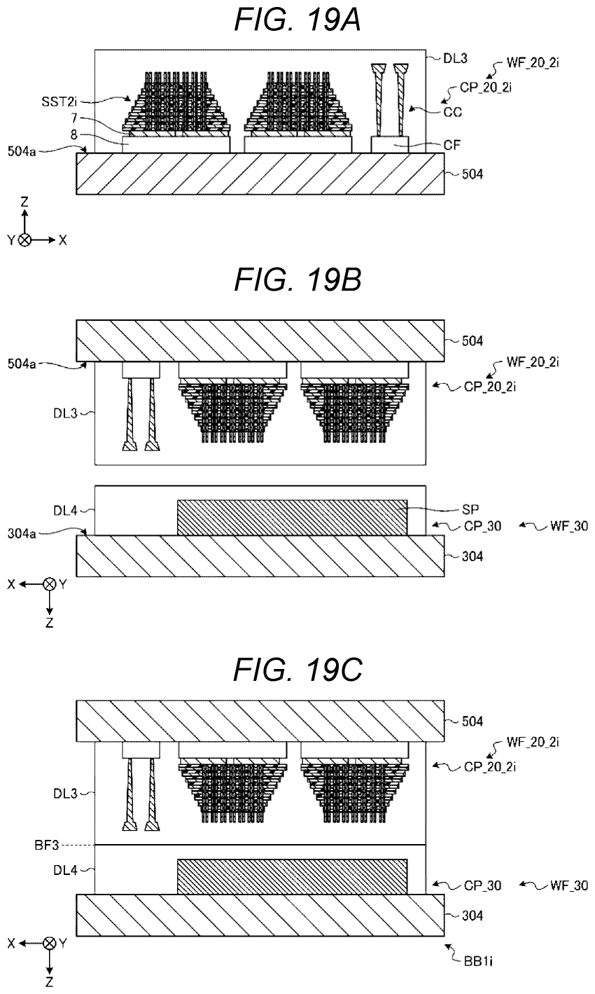

Further, according to a third modification example of the embodiment, the semiconductor memory device 1i (see FIGS. 10 to 12) may be manufactured as illustrated in FIGS. 19A to 21B. FIGS. 19A to 19C, FIGS. 20A to 20C, and FIGS. 21A and 21B are XZ cross-sectional views illustrating a method of manufacturing the semiconductor memory device 1i.

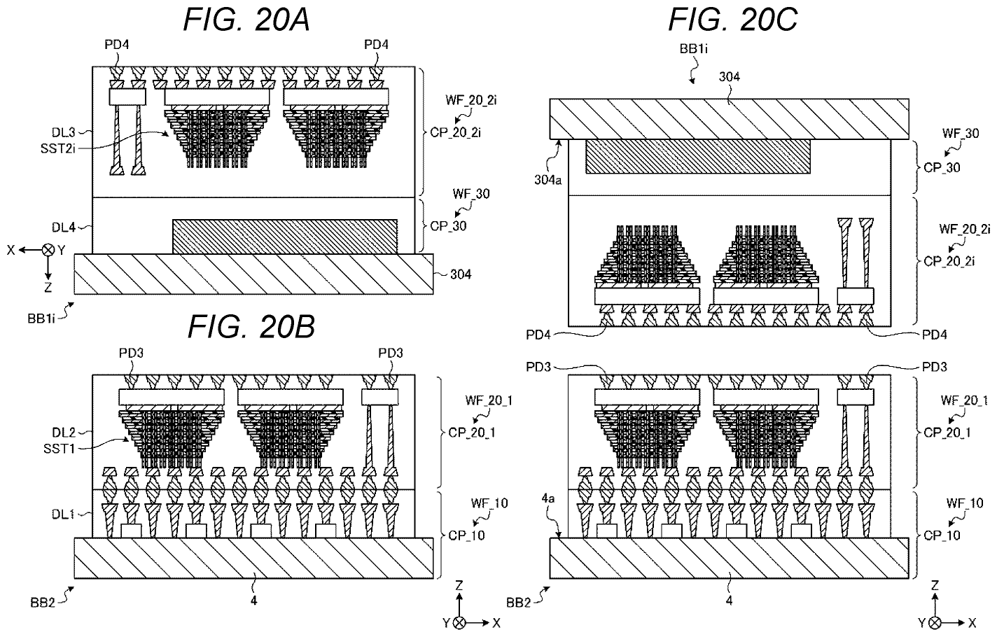

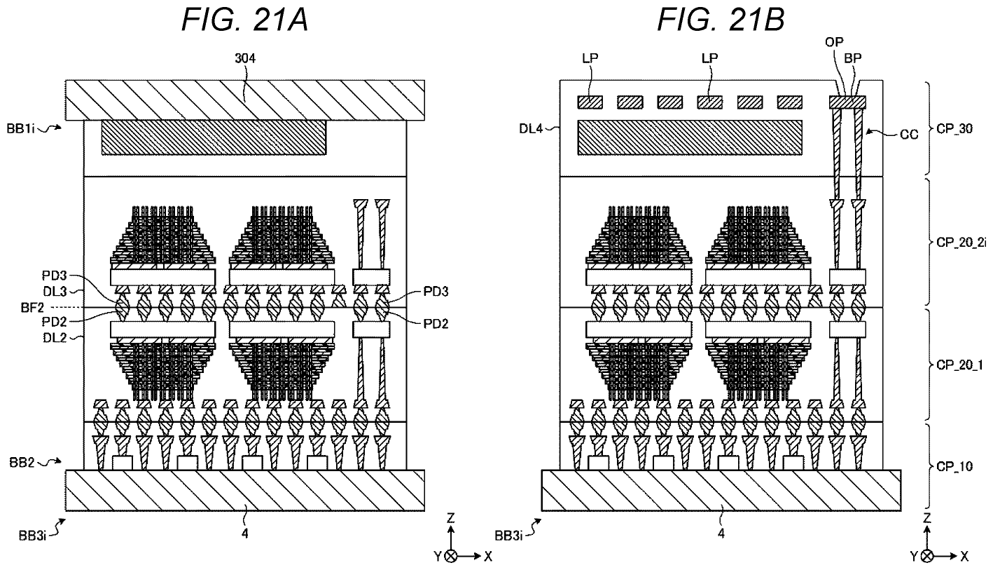

In the method of manufacturing the semiconductor memory device 1i, steps illustrated in FIGS. 19A to 19C and steps illustrated in FIGS. 16A to 16C are performed in parallel, and thereafter, FIGS. 20A to 20C and FIGS. 21A to 21B are performed. The respective steps are actually performed by using a substrate WF on which a plurality of chip regions CP are mounted, as illustrated in FIG. 15A. For the sake of simplification, each XZ cross-sectional view illustrates a cross section of the substrate WF on which one chip region CP is mounted.

In the step illustrated in FIG. 19A, a substrate 504 is prepared. The substrate 504 may be formed of a material with a semiconductor (for example, silicon) as a main component. The substrate 504 has a main surface 504a on the −Z side. Thereafter, a structure is formed in which the conductive layer 8, the conductive layer 7, and the stacked body SST2i are stacked in the Z direction in the same manner as in the step illustrated in FIG. 14A. A plug CC and a conductive film CF are formed at positions shifted in the XY directions from the stacked body SST2i. Thereby, a structure of a substrate (array substrate) WF_20_2i including a chip region CP_20_2i corresponding to a chip 20_2i is formed.

In the step illustrated in FIG. 19B, a structure of a substrate (supporting substrate) WF_30 including a chip region CP_30 corresponding to the chip 30 is formed in the same manner as in the step illustrated in FIG. 14D.

Thereafter, a surface on the +Z side of the insulating film DL3 and a surface on the −Z side of the insulating film DL4 may be activated by plasma irradiation or the like. The substrate 504 and the substrate 304 are disposed such that the main surface 504a and the main surface 304a face each other.

In the step illustrated in FIG. 19C, the substrate 504 and the substrate 304 are brought close to each other in the Z direction, and a surface on the +Z side of the insulating film DL3 is bonded to a surface on the −Z side of the insulating film DL4. At this time, the substrate 504 and the substrate 304 may be heated and pressurized. Thereby, a bonded body BBli is obtained in which the substrate WF_20_2i including the chip region CP_20_2i and the substrate WF_30 including the chip region CP_30 are bonded to each other at the bonding surface BF3.

Thereafter, the substrate 504 is removed. The removal of the substrate 504 may be performed by polishing the substrate 504 from the −Z side.

Meanwhile, the steps illustrated in FIGS. 16A to 16C are performed in the same manner as in the second modification example of the embodiment to obtain a bonded body BB2, and the substrate 404 is removed from the bonded body BB2.

In the step illustrated in FIG. 20A, an insulating film DL3 is further deposited on the −Z side of the bonded body BBli obtained in FIG. 19C, and a hole is formed in the insulating film DL3 for each chip region CP_20_2i. The hole is filled with a conductive material (for example, a material containing copper as a main component) to form the electrode PD4. Thereafter, a surface on the −Z side of the bonded body BBli may be activated by plasma irradiation or the like.

In the step illustrated in FIG. 20B, an insulating film DL2 is further deposited on the +Z side of the bonded body BB2 obtained in FIG. 16C, and a hole is formed in the insulating film DL2 for each chip region CP_20_1. The hole is filled with a conductive material (for example, a material containing copper as a main component) to form the electrode PD3. Thereafter, a surface on the +Z side of the bonded body BB2 may be activated by plasma irradiation or the like.

In the step illustrated in FIG. 20C, the bonded body BBli in FIG. 20A and the bonded body BB2 in FIG. 20B are disposed such that the main surface 304a and the main surface 4a face each other. At this time, the bonded body BBli and the bonded body BB2 face each other such that an XY position of the electrode PD4 matches an XY position of the electrode PD3.

In the step illustrated in FIG. 21A, the bonded body BBli and the bonded body BB2 are brought close to each other in the Z direction, and a surface on the −Z side of the insulating film DL3 is bonded to a surface on the +Z side of the insulating film DL2. At this time, the bonded body BBli and the bonded body BB2 may be heated and pressurized. Thereby, a bonded body BB3i is obtained in which the bonded body BBli and the bonded body BB2 are bonded to each other at the bonding surface BF2. At this time, the electrode PD4 is bonded to the electrode PD3.

In the step illustrated in FIG. 21B, the substrate 304 is removed from the bonded body BB3i. The removal of the substrate 304 may be performed by polishing the bonded body BB3i from the +Z side. A surface on the +Z side of the insulating film DL4 in the bonded body BB3i is exposed. A hole is formed in the insulating film DL4, and the hole is filled with a conductive material (for example, a material containing tungsten as a main component) to form the plug CC. A conductive film formed of a conductive material (for example, a material containing aluminum or the like as a main component) is deposited on the insulating film DL4 and is patterned. Thereby, a conductive film LP and an electrode BP are formed. Thereafter, the insulating film DL4 is further deposited, and an opening OP is formed in a region corresponding to the electrode BP. The opening OP exposes a surface on the +Z side of the electrode BP. Thereby, a bonded body BB3i including a plurality of chip regions CP is obtained.

In each chip region CP, the chip regions CP_10, CP_20_1, CP_20_2i, and CP_30 are stacked in the Z direction. By dicing the bonded body BB3i at boundaries between the chip regions CP, the plurality of chip regions CP are separated into pieces. Thereby, the semiconductor memory device 1i including the chip regions CP is obtained.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
a first chip;
a second chip bonded to the first chip;
a third chip bonded to the second chip on a side opposite to the first chip; and
a fourth chip bonded to the third chip on a side opposite to the second chip, wherein
the third chip includes a first stacked body in which a plurality of first conductive layers are stacked in a first direction through a first insulating layer, a plurality of first semiconductor films each extending in the first direction through the first stacked body, and a plurality of first insulating films each extending in the first direction outside the first semiconductor film through the first stacked body,
the second chip includes a second stacked body in which a plurality of second conductive layers are stacked in the first direction through a second insulating layer, a plurality of second semiconductor films each extending in the first direction through the second stacked body, and a plurality of second insulating films each extending in the first direction outside the second semiconductor film through the second stacked body,
each of the first conductive layers longitudinally extends in a second direction perpendicular to the first direction,
each of the second conductive layers longitudinally extends in the second direction, and
the fourth chip includes a plurality of line patterns each extending in the second direction and aligned with each other in a third direction perpendicular to the first direction and the second direction.

2. The semiconductor memory device of claim 1, wherein
the third chip includes a plurality of bit lines each extending in the second direction and aligned with each other in the first direction, and
a width of each of the line patterns is greater than a width of each of the plurality of bit lines.

3. The semiconductor memory device of claim 1, wherein
the third chip includes a plurality of bit lines each extending in the second direction and aligned with each other in the first direction, and
a film thickness of each of the line patterns is greater than a film thickness of each of the plurality of bit lines.

4. The semiconductor memory device of claim 1, wherein
the plurality of line patterns are disposed at a position corresponding to at least one of the first stacked body or the second stacked body.

5. The semiconductor memory device of claim 1, wherein
the fourth chip further includes an electrode having a surface exposed at an opening, and
the plurality of line patterns are disposed at a position that does not overlap the electrode when viewed from the top.

6. The semiconductor memory device of claim 5, wherein
the fourth chip further includes a conductive film disposed above the plurality of line patterns, the conductive film and the electrode being disposed at a same depth within the fourth chip.

7. The semiconductor memory device of claim 1, wherein
the fourth chip further includes an insulating film disposed around the plurality of line patterns, and
the plurality of line patterns have compositions different from a composition of the insulating film.

8. The semiconductor memory device of claim 1, wherein
the fourth chip further includes an insulating film disposed around the plurality of line patterns, and
the plurality of line patterns have film densities different from a film density of the insulating film.

9. The semiconductor memory device of claim 1, wherein
the first conductive layer further extends in the third direction.

10. The semiconductor memory device of claim 1, wherein
the second conductive layer further extends in the third direction.

11. The semiconductor memory device of claim 1, wherein the first stacked body has a first isosceles trapezoidal shape with a first side extending longer in the second direction than a second side, wherein the second stacked body has a second isosceles trapezoidal shape with a third side extending longer in the second direction than a fourth side.

12. The semiconductor memory device of claim 11, wherein the second side faces the third side.

13. The semiconductor memory device of claim 11, wherein the first side faces the third side.

14. A semiconductor memory device, comprising:
a first chip;
a second chip bonded to the first chip;
a third chip bonded to the second chip on a side opposite to the first chip; and
a fourth chip bonded to the third chip on a side opposite to the second chip, wherein
the third chip includes a first stacked body, the first stacked body including a plurality of first conductive layers stacked in a first direction,
the second chip includes a second stacked body, the second stacked body including a plurality of second conductive layers stacked in the first direction,
the first conductive layer longitudinally extends in a second direction perpendicular to the first direction,
the second conductive layer longitudinally extends in the second direction, and
the fourth chip includes a plurality of line patterns each extending in the second direction and aligned with each other in a third direction perpendicular to the first direction and the second direction.

15. The semiconductor memory device of claim 14, wherein
the first stacked body further includes:
a plurality of first semiconductor films each extending in the first direction, and a plurality of first insulating films each extending in the first direction outside the first semiconductor film; and
the second stacked body further includes:
a plurality of second semiconductor films each extending in the first direction, and a plurality of second insulating films each extending in the first direction outside the second semiconductor film.

16. The semiconductor memory device of claim 14, wherein
the third chip includes a plurality of bit lines each extending in the second direction and aligned with each other in the first direction, and
a width of each of the line patterns is greater than a width of each of the plurality of bit lines.

17. The semiconductor memory device of claim 14, wherein
the third chip includes a plurality of bit lines each extending in the second direction and aligned with each other in the first direction, and
a film thickness of each of the line patterns is greater than a film thickness of each of the plurality of bit lines.
